(19) United States
(12) Patent Application Publication
(10) Pub. No.: US 2025/0275146 A1
(43) Pub. Date: Aug. 28, 2025

(54) APPARATUS AND METHODS FOR REDUCING NUMBER OF LAYOUT TRACKS FOR SENSE AMPLIFIERS

(71) Applicant: Western Digital Technologies, Inc., San Jose, CA (US)

(72) Inventors: Qing Shao, San Jose, CA (US); Fumiaki Toyama, Cupertino, CA (US)

(73) Assignee: Western Digital Technologies, Inc., San Jose, CA (US)

(21) Appl. No.: 18/587,700

(22) Filed: Feb. 26, 2024

(51) Int. Cl. H10B 43/40; G11C 16/26; H10B 41/41

(52) U.S. Cl. CPC H10B 43/40; H10B 41/41; G11C 16/26

(57) ABSTRACT

An apparatus is provided that includes a first sense amplifier and a second sense amplifier, and a second conductor layer that includes two first conductors, two second conductors substantially parallel to the two first conductors, and a landing pad. The first conductors each include one integrated circuit layout track on the second conductor layer. The second conductors each include one integrated circuit layout track on the second conductor layer. The landing pad includes two integrated circuit layout tracks on the second conductor layer. The apparatus includes a total of five integrated circuit layout tracks on the second conductor layer.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may be non-volatile memory or volatile memory. A non-volatile memory allows information to be stored and retained even when the non-volatile memory is not connected to a source of power (e.g., a battery).

Non-volatile memory devices include one or more memory chips having multiple arrays of memory cells. The memory arrays may have associated decoders and circuits for performing read, write, and erase operations. Memory cells within the arrays may be arranged in horizontal rows and vertical columns. Each row may be addressed by a word line, and each column may be addressed by a bit line. Data may be loaded into columns of the array using a series of data busses. Each column may hold a predefined unit of data, for instance, a word encompassing two bytes of information.

The cost of a non-volatile memory device depends on the size of semiconductor die used to implement the memory device. Thus, to reduce cost it is desirable to reduce feature sizes fabricated on the semiconductor die. However, because of semiconductor manufacturing process limits, some features reach a minimum feature size and cannot be made smaller. Thus, various challenges exist in reducing the size of non-volatile memory devices.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 4A is a perspective view of a portion of one embodiment of a monolithic three dimensional memory structure.

FIG. 4B is a block diagram of one embodiment of a memory structure having four planes.

FIG. 4C depicts a top view of a portion of one embodiment of a block of memory cells.

FIG. 4D depicts a cross sectional view of a portion of one embodiment of a block of memory cells.

FIG. 4E depicts a cross sectional view of a portion of one embodiment of a block of memory cells.

FIG. 4F is a cross sectional view of one embodiment of a vertical column of memory cells.

FIG. 4G is a schematic of a plurality of NAND strings in multiple regions of a same block.

FIG. 5A depicts a top view of a memory die that includes eight planes.

FIG. 5B depicts a top view of a control die.

FIG. 5C is a top view of an embodiment of sense amplifier region of FIG. 5B.

FIG. 6A depicts a simplified functional view of a portion of a sense amplifier region of FIG. 5C.

FIG. 6B depicts a plan view of an example layout of sense amplifier unit circuits of FIG. 6A.

FIG. 7A is a top view of an alternative embodiment of sense amplifier region of FIG. 5B.

FIG. 7B depicts an alternative simplified functional view of a portion of a sense amplifier region of FIG. 5C.

FIG. 7C depicts a plan view of an example layout of sense amplifier unit circuits of FIG. 7B.

FIG. 8 is a flow diagram of an embodiment of a method of fabricating a control die that includes circuits for controlling a memory die that includes a three dimensional non-volatile memory.

### DETAILED DESCRIPTION

Technology is described for reducing the layout size of sense amplifiers for non-volatile memory devices. In embodiments, sense amplifiers are disposed in sense amplifier tiers that each include multiple sense amplifier unit circuits. In an embodiment, each sense amplifier unit circuit includes active areas for forming two sense amplifiers.

In an embodiment, each sense amplifier unit circuit also includes a conductor layer that includes two bit lines, two data bus lines and a landing pad. The two bit lines, two data bus lines and a landing pad in each sense amplifier unit circuit are conventionally require six integrated circuit layout tracks on the conductor layer.

Technology is described for configuring the two bit lines, two data bus lines and a landing pad in each sense amplifier unit circuit in a total of five integrated circuit layout tracks on the conductor layer. Without wanting to be bound by any particular theory, it is believe that by using five integrated circuit layout tracks on the conductor layer per two sense amplifiers the size of the sense amplifiers can be reduced.

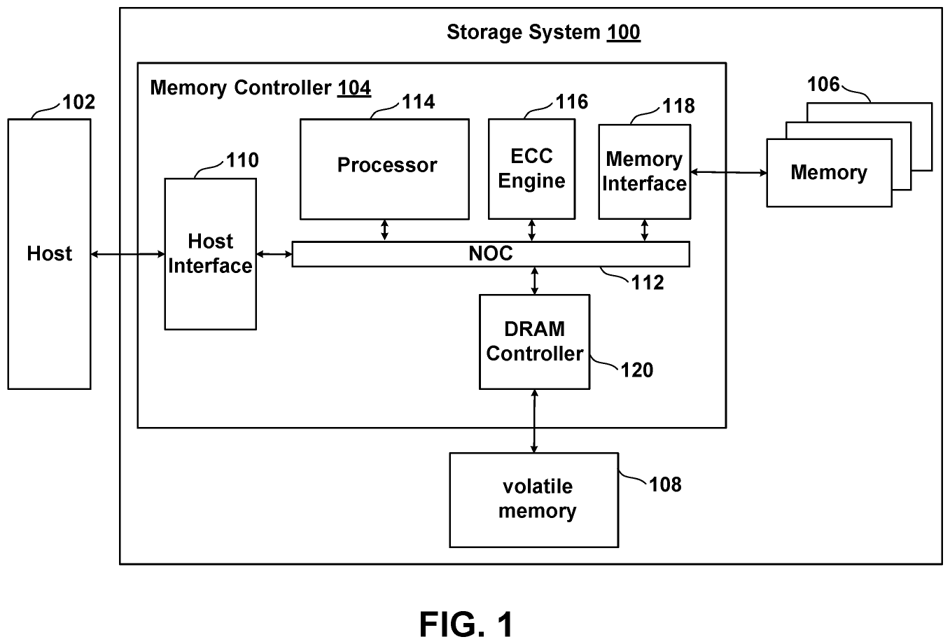

FIG. 1 is a block diagram of one embodiment of a storage system 100 that implements the proposed technology described herein. In one embodiment, storage system 100 is a solid state drive (“SSD”). Storage system 100 also can be a memory card, USB drive or other type of storage system. The proposed technology is not limited to any one type of memory system.

Storage system 100 is connected to a host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 104 connected to non-volatile memory 106 and local high speed volatile memory 108 (e.g., DRAM). Local high speed volatile memory 108 is used by memory controller 104 to perform certain functions. For example, local high speed volatile memory 108 stores logical to physical address translation tables (“L2P tables”).

Memory controller 104 includes a host interface 110 that is connected to and in communication with host 102. In one embodiment, host interface 110 implements a NVM Express (NVMe) over PCI Express (PCIe). Other interfaces can also be used, such as SCSI, SATA, etc. Host interface 110 also is connected to a network-on-chip (NOC) 112.

A NOC is a communication subsystem on an integrated circuit. NOC's can span synchronous and asynchronous clock domains or use un-clocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs.

The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 112 can be replaced by a bus.

Connected to and in communication with NOC 112 is a processor 114, an ECC engine 116, a memory interface 118, and a DRAM controller 120. DRAM controller 120 is used to operate and communicate with local high speed volatile memory 108 (e.g., DRAM). In other embodiments, local high speed volatile memory 108 can be SRAM or another type of volatile memory.

Processor 114 performs the various controller memory operations, such as programming, erasing, reading, and memory management processes. In one embodiment, processor 114 is programmed by firmware. In other embodiments, processor 114 is a custom and dedicated hardware circuit without any software. Processor 114 also implements a translation module, as a software/firmware process or as a dedicated hardware circuit.

In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die.

To implement this system, memory controller 104 (e.g., the translation module) performs address translation between the logical addresses used by the host and the physical addresses used by the memory die. One example implementation is to maintain L2P tables that identify the current translation between logical addresses and physical addresses. An entry in the L2P table may include an identification of a logical address and corresponding physical address. Although logical address to physical address tables (or L2P tables) include the word “tables” they need not literally be tables.

Instead, the logical address to physical address tables (or L2P tables) can be any type of data structure. In some examples, the memory space of a storage system is so large that the local memory 108 cannot hold all of the L2P tables. In such a case, the entire set of L2P tables are stored in non-volatile memory 106 and a subset of the L2P tables are cached (L2P cache) in the local high speed volatile memory 108.

ECC engine 116 performs error correction services. For example, ECC engine 116 performs data encoding and decoding, as per the implemented ECC technique. In one embodiment, ECC engine 116 is an electrical circuit programmed by software. For example, ECC engine 116 can be a processor that can be programmed. In other embodiments, ECC engine 116 is a custom and dedicated hardware circuit without any software. In another embodiment, the function of ECC engine 116 is implemented by processor 114.

Memory interface 118 communicates with non-volatile memory 106. In one embodiment, memory interface provides a Toggle Mode interface. Other interfaces also can be used. In some example implementations, memory interface 118 (or another portion of controller 104) implements a scheduler and buffer for transmitting data to and receiving data from one or more memory die.

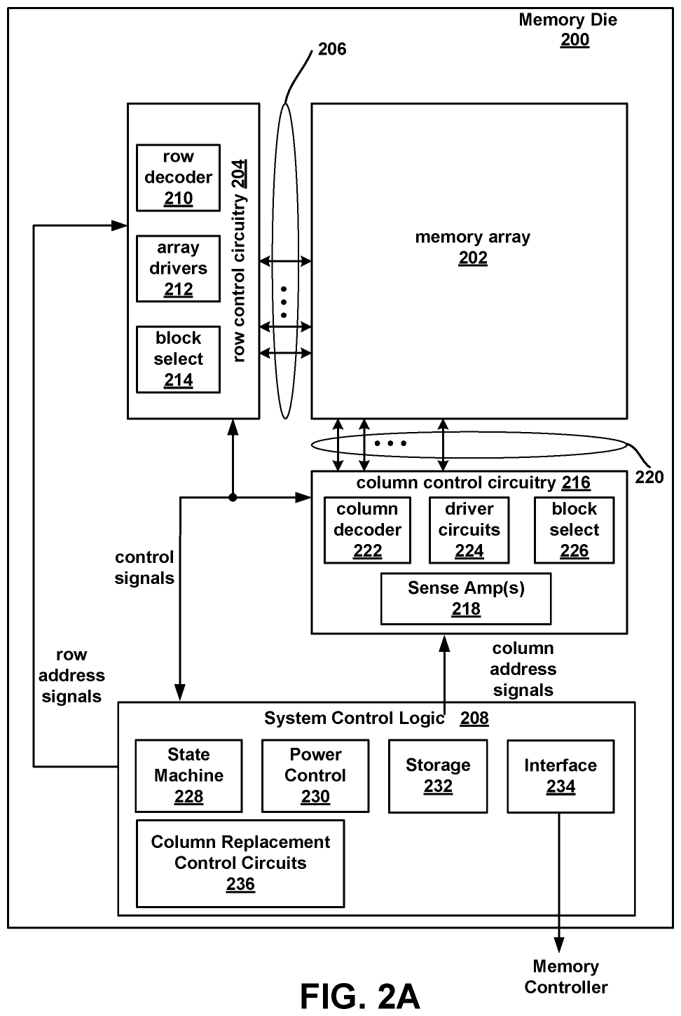

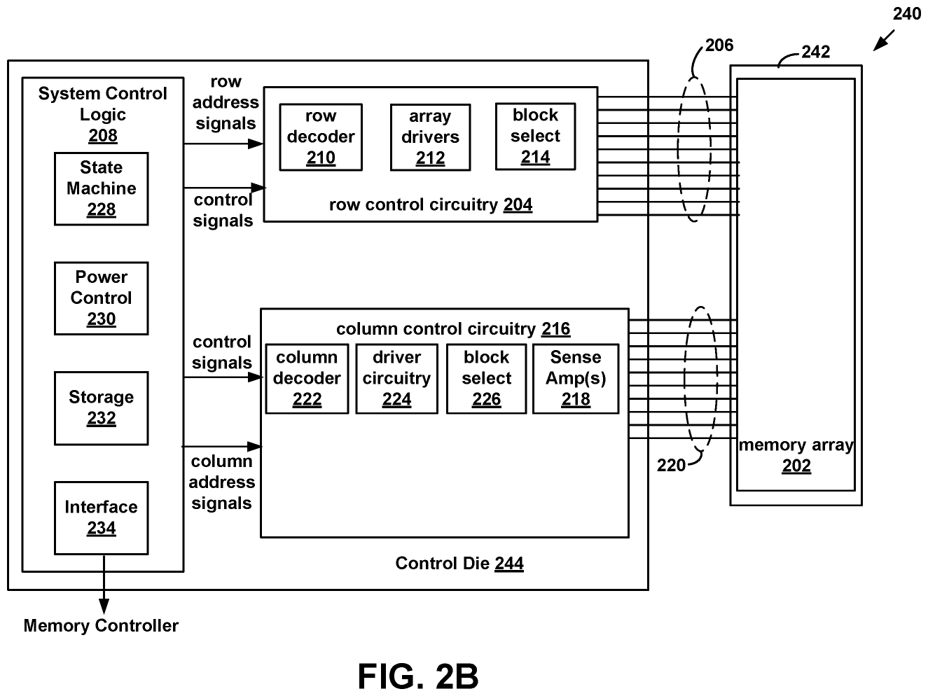

In one embodiment, non-volatile memory 106 includes one or more memory die. FIG. 2A is a functional block diagrams of one embodiment of a memory die 200 that includes non-volatile memory 106. Each of the one or more memory die of non-volatile memory 106 can be implemented as memory die 200 of FIG. 2A. The components depicted in FIG. 2A are electrical circuits.

Memory die 200 includes a memory array 202 that can include non-volatile memory cells, as described in more detail below. The array terminal lines of memory array 202 include the various layer(s) of word lines organized as rows, and the various layer(s) of bit lines organized as columns. However, other orientations can also be implemented.

Memory die 200 includes row control circuitry 204, whose outputs 206 are connected to respective word lines of the memory array 202. Row control circuitry 204 receives a group of M row address signals and one or more various control signals from system control logic circuit 208, and typically may include such circuits as row decoders 210, array terminal drivers 212, and block select circuitry 214 for both reading and writing (programming) operations.

Row control circuitry 204 also may include read/write circuitry. Memory die 200 also includes column control circuitry 216 including sense amplifier(s) 218 whose input/outputs 220 are connected to respective bit lines of memory array 202. Although only a single block is shown for memory array 202, a memory die can include multiple arrays that can be individually accessed.

Column control circuitry 216 receives a group of N column address signals and one or more various control signals from system control logic 208, and typically may include such circuits as column decoders 222, array terminal receivers or driver circuits 224, block select circuitry 226, as well as read/write circuitry, and I/O multiplexers.

System control logic 208 receives data and commands from memory controller 104 (FIG. 1) and provides output data and status to host 102. In some embodiments, system control logic 208 (which includes one or more electrical circuits) includes a state machine 228 that provides die-level control of memory operations.

In one embodiment, state machine 228 is programmable by software. In other embodiments, state machine 228 does not use software and is completely implemented in hardware (e.g., electrical circuits). In another embodiment, state machine 228 is replaced by a micro-controller or microprocessor, either on or off the memory chip.

System control logic 208 also can include a power control module 230 that controls the power and voltages supplied to the rows and columns of memory structure 202 during memory operations and may include charge pumps and regulator circuit for creating regulating voltages. System control logic 208 includes storage 232 (e.g., RAM, registers, latches, etc.), which may be used to store parameters for operating memory array 202.

Commands and data are transferred between memory controller 104 and memory die 200 via memory controller interface 234 (also referred to as a “communication interface”). Memory controller interface 234 is an electrical interface for communicating with memory controller 104. Examples of memory controller interface 234 include a Toggle Mode Interface and an Open NAND Flash Interface (ONFI). Other I/O interfaces can also be used.

In some embodiments, all elements of memory die 200, including the system control logic 208, can be formed as part of a single die. In other embodiments, some or all of the system control logic 208 can be formed on a different die.

In one embodiment, memory structure 202 comprises a three-dimensional memory array of non-volatile memory cells in which multiple memory levels are formed above a single substrate, such as a wafer. Memory structure 202 may include any type of non-volatile memory that are monolithically formed in one or more physical levels of memory cells having an active area disposed above a silicon (or other type of) substrate.

In one example, the non-volatile memory cells includes vertical NAND strings with charge-storing layers such as a floating gate or charge-trapping layers. Each memory cell in a NAND string has a control gate that is coupled to a corresponding word line, and each NAND string is coupled to a corresponding bit line. Each bit line is coupled to a corresponding sense module.

The threshold voltage of each memory cell is controlled by the amount of charge that is retained on the charge storage material. To program a memory cell in a NAND string, one or more program pulses are applied to the word line coupled to the memory cell to change an amount of charge on the charge storage material, and hence change the threshold voltage of the memory cell. To read a memory cell, the corresponding bit line coupled to the NAND string is coupled to a sense module to determine the threshold voltage of the memory cell.

In another embodiment, memory structure 202 includes a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein.

Other examples of suitable technologies for memory cells of memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell.

A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells.

In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb₂Te₃ super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light.

In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to memory structure 202. However, this reduces the area of the memory die available for the peripheral circuitry. This can place quite severe restrictions on these elements of the peripheral circuitry.

For example, the need to fit sense amplifiers within the available area can be a significant restriction on sense amplifier design architectures. With respect to system control logic 208, reduced availability of area can limit the available functions that can be implemented on-chip. Consequently, a basic trade-off in the design of a memory die for the storage system 100 is the amount of area to devote to memory structure 202 and the amount of area to devote to the peripheral circuitry.

Another area in which memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based.

For example, elements such as sense amplifiers, charge pumps, logic elements in a state machine, and other peripheral circuitry in system control logic 208 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed die that are then bonded together. More specifically, memory structure 202 can be formed on one die (referred to as the memory die) and some or all of the peripheral circuitry elements, including one or more control circuits, can be formed on a separate die (referred to as the control die).

For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology.

For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array.

The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 240. One or more integrated memory assemblies 240 may be used to implement the non-volatile memory 106 of storage system 100.

Integrated memory assembly 240 includes two types of semiconductor die (or more succinctly, “die”). Memory die 242 includes memory structure 202. Memory structure 202 includes non-volatile memory cells. Control die 244 includes control circuitry 208, 216, and 204 (as described above). In some embodiments, control die 244 is configured to connect to memory structure 202 in memory die 242. In some embodiments, memory die 242 and control die 244 are bonded together.

FIG. 2B shows an example of the peripheral circuitry, including control circuits, formed in a peripheral circuit or control die 244 coupled to memory structure 202 formed in memory die 242. Common components are labelled similarly to FIG. 2A. System control logic 208, row control circuitry 204, and column control circuitry 216 are located in control die 244. In some embodiments, all or a portion of column control circuitry 216 and all or a portion of row control circuitry 204 are located on memory die 242. In some embodiments, some of the circuitry in system control logic 208 is located on memory die 242.

System control logic 208, row control circuitry 204, and column control circuitry 216 may be formed by a common process (e.g., CMOS process), so that adding elements and functions, such as ECC, more typically found on a memory controller 104 may require few or no additional process steps (i.e., the same process steps used to fabricate controller 104 may also be used to fabricate system control logic 208, row control circuitry 204, and column control circuitry 216).

Thus, while moving such circuits from a die such as memory 242 may reduce the number of steps needed to fabricate such a die, adding such circuits to a die such as control die 244 may not require many additional process steps. Control die 244 also could be referred to as a CMOS die, due to the use of CMOS technology to implement some or all of control circuitry 204, 208, 216.

FIG. 2B shows column control circuitry 216 including sense amplifier(s) 218 on control die 244 coupled to memory structure 202 on memory die 242 through electrical paths 220. For example, electrical paths 220 may provide electrical connection between column decoder 222, driver circuitry 224, and block select 226 and bit lines of memory structure 202. In an embodiment, column control circuitry 216 also includes column replacement control circuits 236, described in more detail below.

Electrical paths may extend from column control circuitry 216 in control die 244 through pads on control die 244 that are bonded to corresponding pads of the memory die 242, which are connected to bit lines of memory structure 202. Each bit line of memory structure 202 may have a corresponding electrical path in electrical paths 220, including a pair of bond pads, which connects to column control circuitry 216.

Similarly, row control circuitry 204, including row decoder 210, array drivers 212, and block select 214 are coupled to memory structure 202 through electrical paths 206. Each of electrical path 206 may correspond to a word line, dummy word line, or select gate line. Additional electrical paths may also be provided between control die 244 and memory die 242.

For purposes of this document, the phrases “a control circuit” or “one or more control circuits” can include any one of or any combination of memory controller 104, state machine 228, all or a portion of system control logic 208, all or a portion of row control circuitry 204, all or a portion of column control circuitry 216, a microcontroller, a microprocessor, and/or other similar functioned circuits.

The control circuit can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

In some embodiments, there is more than one control die 244 and more than one memory die 242 in an integrated memory assembly 240. In some embodiments, the integrated memory assembly 240 includes a stack of multiple control die 244 and multiple memory die 242.

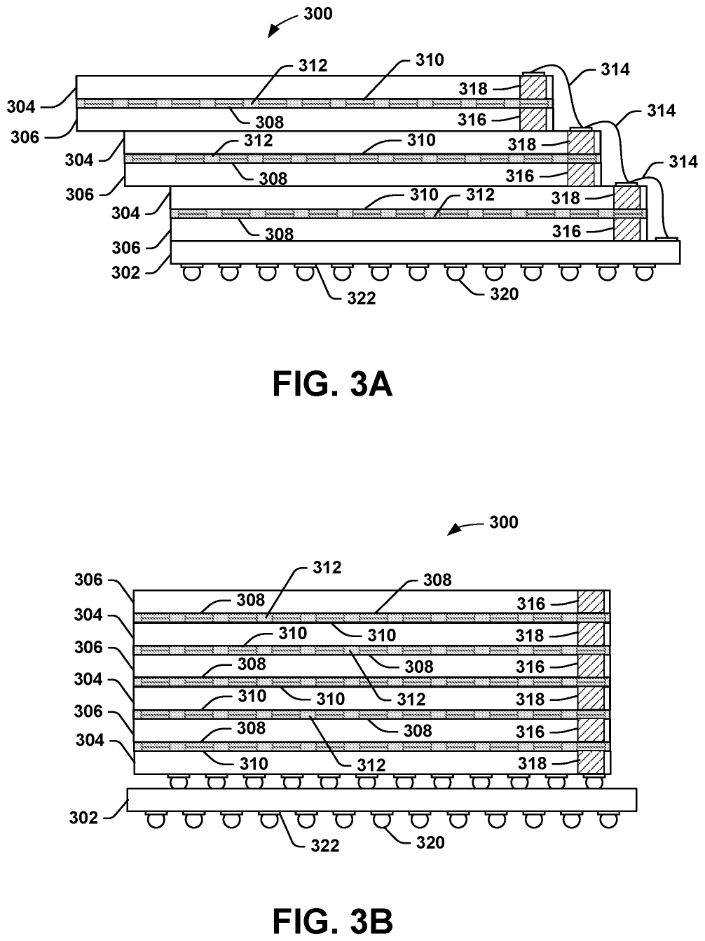

FIG. 3A depicts a side view of an embodiment of an integrated memory assembly 300 stacked on a substrate 302 (e.g., a stack including control die 304 and memory die 306). The integrated memory assembly 300 has three control die 304 and three memory die 306. In some embodiments, there are more than three memory die 306 and more than three control die 304.

Each control die 304 is affixed (e.g., bonded) to at least one memory die 306. Some of the bond pads 308/310 are depicted, although there may be many more bond pads. A space between two die 306, 304 that are bonded together is filled with a solid layer 312, which may be formed from epoxy or other resin or polymer. This solid layer 312 protects the electrical connections between the die 306, 304, and further secures the die together. Various materials may be used as solid layer 312, but in embodiments, it may be Hysol epoxy resin from Henkel Corp., having offices in California, USA.

Integrated memory assembly 300 may for example be stacked with a stepped offset, leaving the bond pads at each level uncovered and accessible from above. Wire bonds 314 connected to the bond pads connect control die 304 to substrate 302. A number of such wire bonds may be formed across the width of each control die 304 (i.e., into the page of FIG. 3A).

A memory die through silicon via (TSV) 316 may be used to route signals through each memory die 306. A control die TSV 318 may be used to route signals through each control die 304. The TSVs 316, 318 may be formed before, during or after formation of the integrated circuits in semiconductor die 306, 304. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 320 optionally may be affixed to contact pads 322 on a lower surface of substrate 302. Solder balls 320 may be used to couple integrated memory assembly 300 electrically and mechanically to a host device such as a printed circuit board. Solder balls 320 may be omitted where the integrated memory assembly 300 is to be used as an LGA package. Solder balls 320 may form a part of an interface between integrated memory assembly 300 and memory controller 104 (FIG. 1).

FIG. 3B depicts a side view of another embodiment of an integrated memory assembly 300 stacked on a substrate 302. The integrated memory assembly 300 of FIG. 3B has three control die 304 and three memory die 306. In some embodiments, there are many more than three memory die 306 and many more than three control die 304. In this example, each control die 304 is bonded to at least one memory die 306. Optionally, a control die 304 may be bonded to two or more memory die 306.

Some of the bond pads 308, 310 are depicted. There may be many more bond pads. A space between two die 306, 304 that are bonded together is filled with a solid layer 312, which may be formed from epoxy or other resin or polymer. In contrast to the example in FIG. 3A, integrated memory assembly 300 of FIG. 3B does not have a stepped offset. A memory die TSV 316 may be used to route signals through each memory die 306. A control die TSV 318 may be used to route signals through each control die 304.

As has been briefly discussed above, control die 304 and memory die 306 may be bonded together. Bond pads on each control die 304 and each memory die 306 may be used to bond the two die together. In some embodiments, the bond pads are bonded directly to each other, without solder or other added material, in a so-called Cu-to-Cu bonding process.

In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension.

Such bonds may be formed at room temperature, though heat also may be applied. In embodiments using cu-to-cu bonding, the bond pads may be about 5 μm square and spaced from each other with a pitch of 5 μm to 5 μm. Although this process is referred to herein as cu-to-cu bonding, this term also may apply even where the bond pads are formed of materials other than copper.

When the area of bond pads is small, it may be difficult to bond the semiconductor die together. The size of and pitch between bond pads may be further reduced by providing a film layer on the surfaces of the semiconductor die including the bond pads. The film layer is provided around the bond pads. When the die are brought together, the bond pads may bond to each other, and the film layers on the respective die may bond to each other.

Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller (or greater) sizes and pitches.

Some embodiments may include a film on surface of control die 304 and memory die 306. Where no such film is initially provided, a space between the die may be under filled with an epoxy or other resin or polymer. The under-fill material may be applied as a liquid which then hardens into a solid layer. This under-fill step protects the electrical connections between control die 304 and memory die 306, and further secures the die together. Various materials may be used as under-fill material, such as Hysol epoxy resin from Henkel Corp., having offices in California, USA.

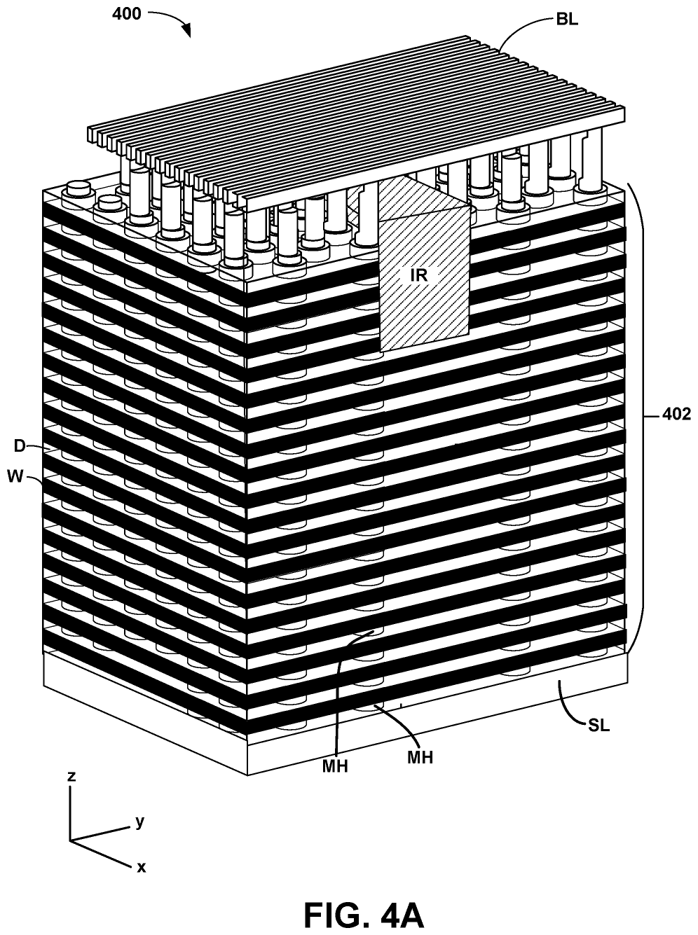

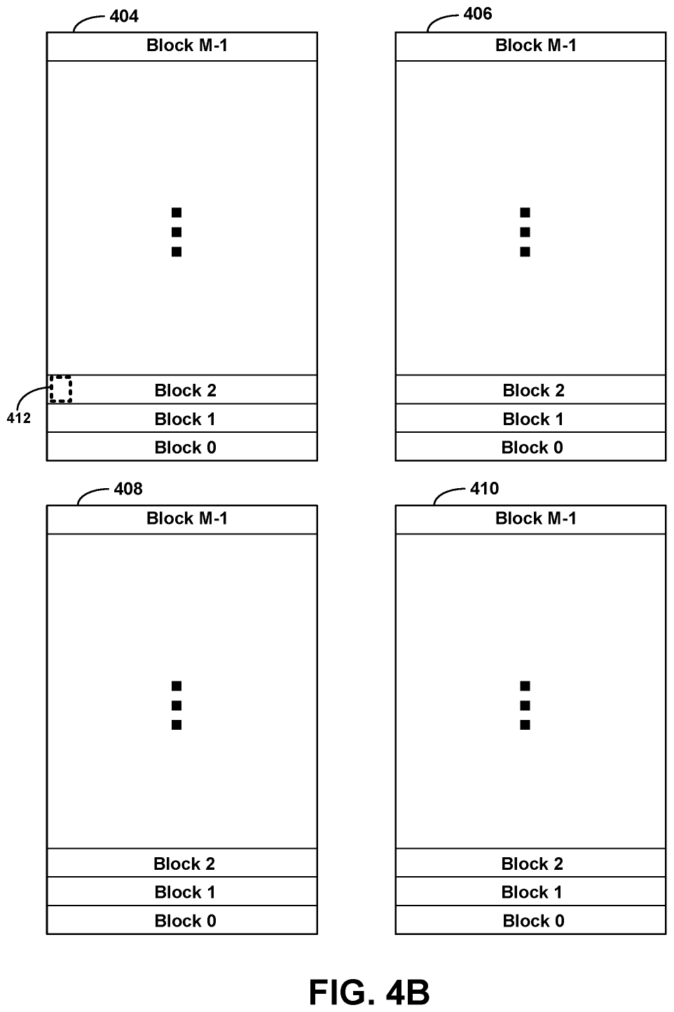

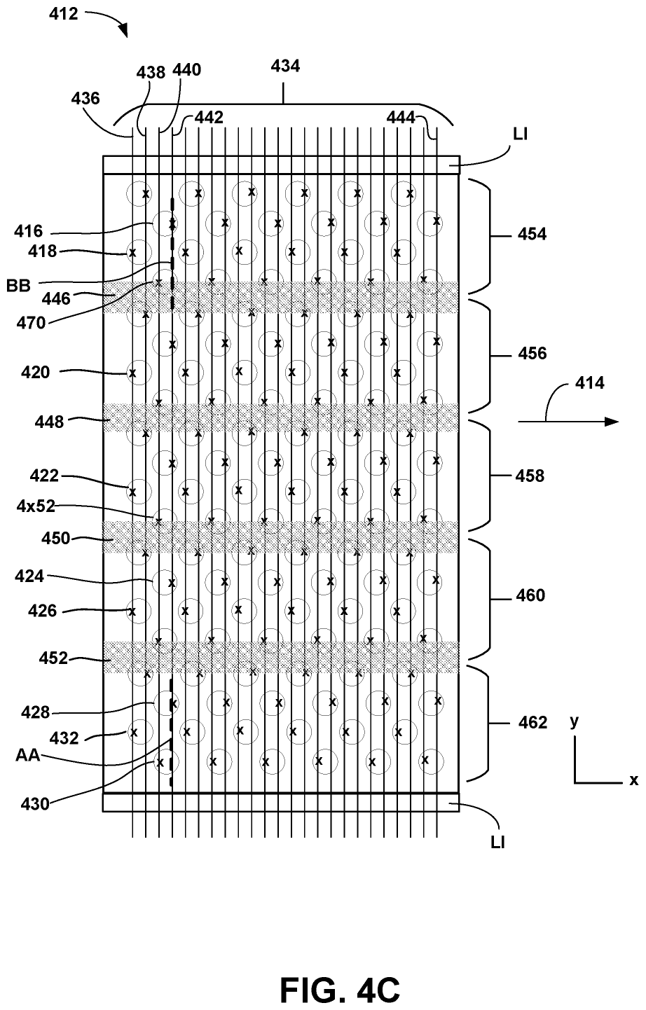

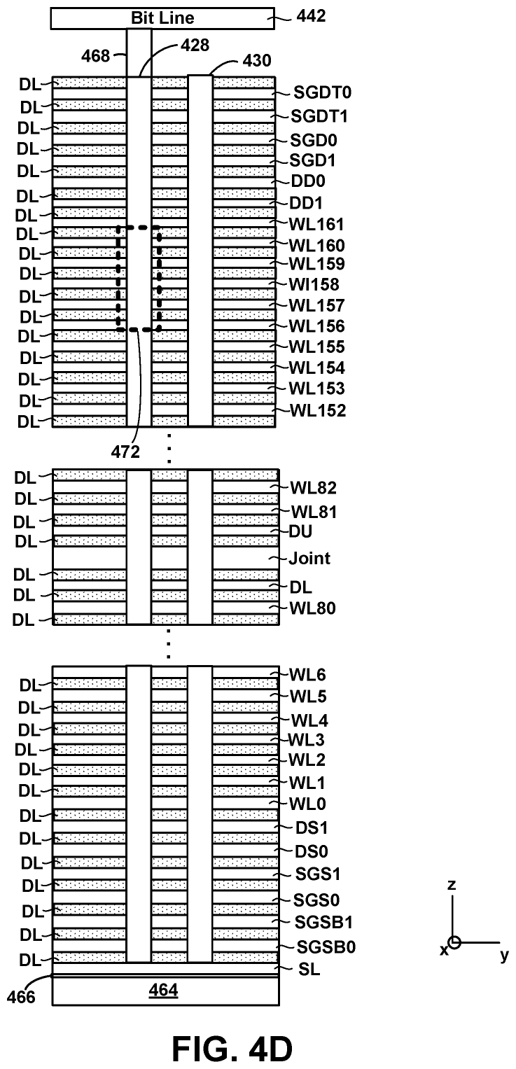

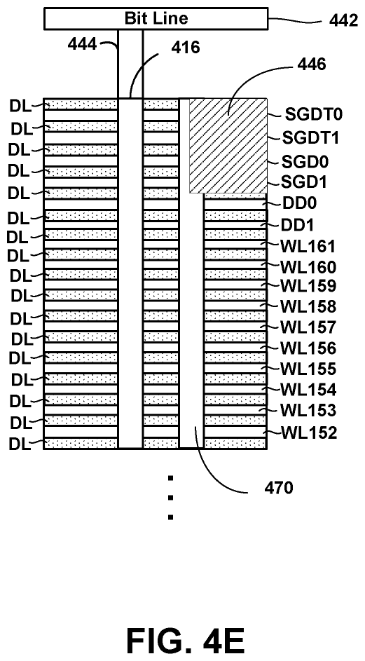

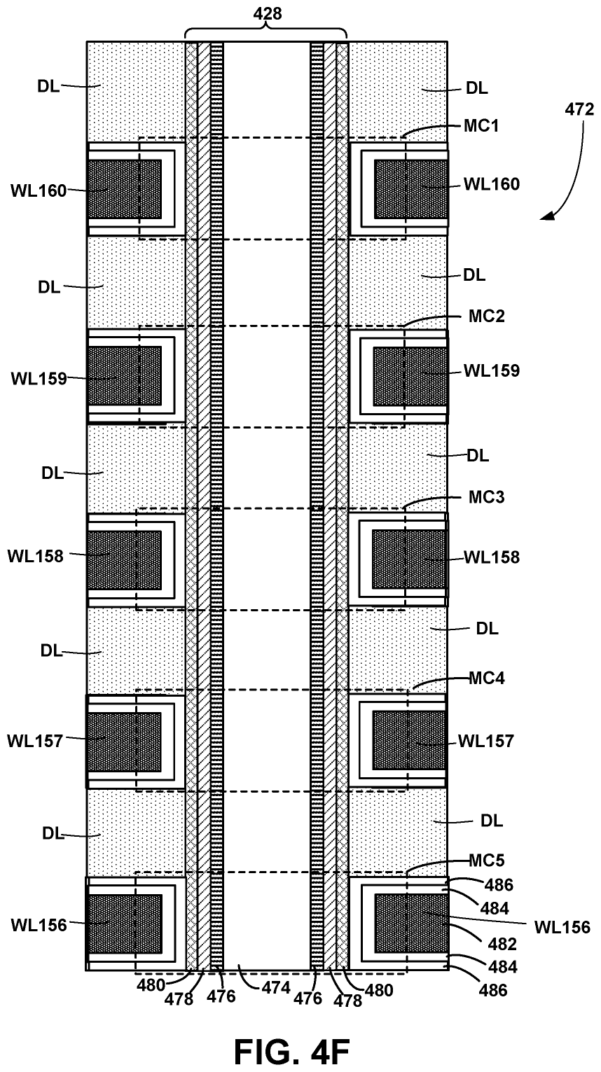

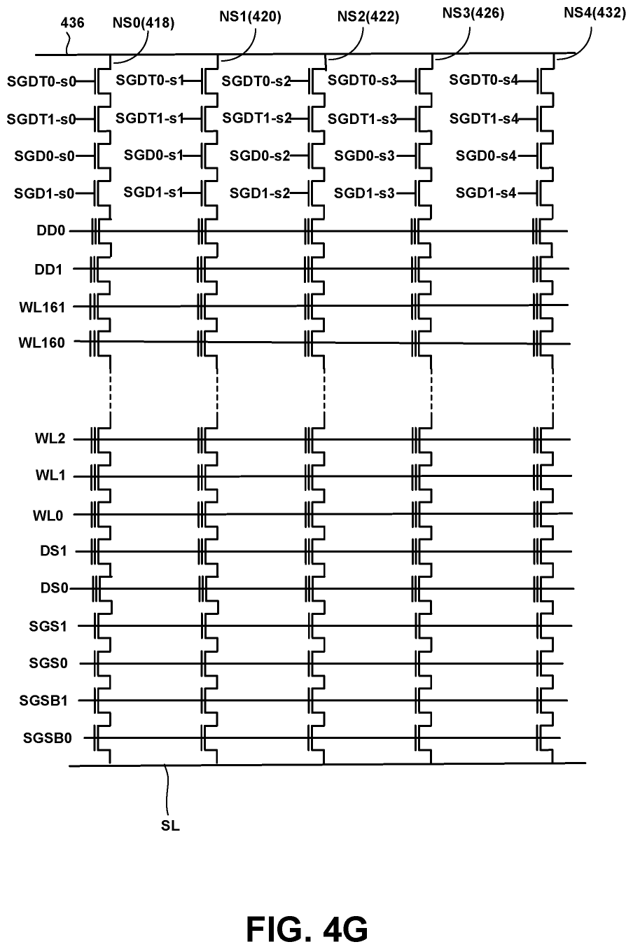

FIG. 4A is a perspective view of a portion of one example embodiment of a monolithic three dimensional memory array/structure included in memory structure 202, which includes a plurality non-volatile memory cells arranged as vertical NAND strings. For example, FIG. 4A shows a portion 400 of one block of memory.

The structure depicted includes a set of bit lines BL positioned above a stack 402 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements.

As will be explained below, in one embodiment the alternating dielectric layers and conductive layers are divided into four or five (or a different number of) regions by isolation regions IR. FIG. 4A shows one isolation region IR separating two regions. Below the alternating dielectric layers and word line layers is a source line layer SL. Memory holes are formed in the stack of alternating dielectric layers and conductive layers.

For example, one of the memory holes is marked as MH. Note that in FIG. 4A, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells.

Each memory cell can store one or more bits of data. Thus, the non-volatile memory cells are arranged in memory holes. More details of the three dimensional monolithic memory array that comprises memory structure 202 is provided below.

FIG. 4B is a block diagram explaining one example organization of memory structure 202, which is divided into four planes 404, 406, 408 and 410. Each plane is then divided into M blocks. In one example, each plane has about 2000 blocks. However, different numbers of blocks and planes can also be used.

In one embodiment, a block of memory cells is a unit of erase. That is, all memory cells of a block are erased together. In other embodiments, blocks can be divided into sub-blocks and the sub-blocks can be the unit of erase. Memory cells also can be grouped into blocks for other reasons, such as to organize the memory structure to enable the signaling and selection circuits.

In some embodiments, a block represents a groups of connected memory cells as the memory cells of a block share a common set of word lines. For example, the word lines for a block are all connected to all of the vertical NAND strings for that block. Although FIG. 4B shows four planes, more or less than four planes can be implemented. In some embodiments, memory structure 202 includes eight planes.

Each block typically is divided into one or more pages. In an embodiment, a page is a unit of programming/writing and a unit of reading. Other units of programming also can be used. In an embodiment, one or more pages of data are typically stored in one row of memory cells. For example, one or more pages of data may be stored in memory cells connected to a common word line. In an embodiment, a page includes data stored in all memory cells connected to a common word line.

FIGS. 4C-4G depict an example three dimensional (“3D”) NAND structure that corresponds to the structure of FIG. 4A and can be used to implement memory structure 202 of FIGS. 2A and 2B. FIG. 4C is a block diagram depicting a top view of a portion 412 of Block 2 of plane 404. As can be seen from FIG. 4C, the block depicted in FIG. 4C extends in the direction of 414. In one embodiment, the memory array has many layers. However, FIG. 4C only shows the top layer.

FIG. 4C depicts a plurality of circles that represent the memory holes, which are also referred to as vertical columns. Each of the memory holes/vertical columns include multiple select transistors (also referred to as a select gate or selection gate) and multiple memory cells. In one embodiment, each memory hole/vertical column implements a NAND string. For example, FIG. 4C labels a subset of the memory holes/vertical columns/NAND strings 416, 418, 420. 422, 424, 426, 428, 430 and 432.

FIG. 4C also depicts a set of bit lines 434, including bit lines 436, 438, 440, 442, . . . 444. FIG. 4C shows twenty four bit lines because only a portion of the block is depicted. It is contemplated that more than twenty four bit lines connected to memory holes/vertical columns of the block. Each of the circles representing memory holes/vertical columns has an “x” to indicate its connection to one bit line. For example, bit line 436 is connected to memory holes/vertical columns 418, 420, 422, 426 and 432.

The block depicted in FIG. 4C includes a set of isolation regions 446, 448, 450 and 452, which are formed of SiO₂. However, other dielectric materials also can be used. Isolation regions 446, 448, 450 and 452 serve to divide the top layers of the block into five regions For example, the top layer depicted in FIG. 4C is divided into regions 454, 456, 458, 460 and 462.

In one embodiment, the isolation regions only divide the layers used to implement select gates so that NAND strings in different regions can be independently selected. In one example implementation, a bit line connects to one memory hole/vertical column/NAND string in each of regions 454, 456, 458, 460 and 462. In that implementation, each block has twenty four rows of active columns and each bit line connects to five rows in each block.

In one embodiment, all of the five memory holes/vertical columns/NAND strings connected to a common bit line are connected to the same set of word lines; therefore, the system uses the drain side selection lines to choose one (or another subset) of the five to be subjected to a memory operation (program, verify, read, and/or erase).

FIG. 4C also shows Line Interconnects LI, which are metal connections to the source line SL from above the memory array. Line Interconnects LI are positioned adjacent regions 454 and 462.

Although FIG. 4C shows each region 454, 456, 458, 460 and 462 having four rows of memory holes/vertical columns, five regions and twenty four rows of memory holes/vertical columns in a block, those exact numbers are an example implementation. Other embodiments may include more or less regions per block, more or less rows of memory holes/vertical columns per region and more or less rows of vertical columns per block.

FIG. 4C also shows the memory holes/vertical columns being staggered. In other embodiments, different patterns of staggering can be used. In some embodiments, the memory holes/vertical columns are not staggered.

FIG. 4D depicts a portion of one embodiment of a three dimensional memory structure 202 showing a cross-sectional view along line AA of FIG. 4C. This cross sectional view cuts through memory holes/vertical columns (NAND strings) 428 and 430 of region 462 (see FIG. 4C).

The structure of FIG. 4D includes two drain side select layers SGD0 and SGD, the source side select layers SGS0 and SGS1, two drain side GIDL generation transistor layers SGDT0 and SGDT1, two source side GIDL generation transistor layers SGSB0 and SGSB1, two drain side dummy word line layers DD0 and DD1, two source side dummy word line layers DS0 and DS1, dummy word line layers DU and DL, one hundred and sixty two word line layers WL0-WL161 for connecting to data memory cells, and dielectric layers DL.

Other embodiments can implement more or less than the numbers described above for FIG. 4D. In one embodiment, SGD0 and SGD1 are connected together; and SGS0 and SGS1 are connected together. In other embodiments, more or less number of SGDs (greater or lesser than two) are connected together, and more or less number of SGS devices (greater or lesser than two) connected together.

In one embodiment, erasing the memory cells is performed using gate induced drain leakage (GIDL), which includes generating charge carriers at the GIDL generation transistors such that the carriers get injected into the charge trapping layers of the NAND strings to change threshold voltage of the memory cells. FIG. 4D shows two GIDL generation transistors at each end of the NAND string; however, in other embodiments there are more or less than three.

Embodiments that use GIDL at both sides of the NAND string may have GIDL generation transistors at both sides. Embodiments that use GIDL at only the drain side of the NAND string may have GIDL generation transistors only at the drain side. Embodiments that use GIDL at only the source side of the NAND string may have GIDL generation transistors only at the source side.

FIG. 4D shows two GIDL generation transistors at each end of the NAND string. It is likely that charge carriers are only generated by GIDL at one of the two GIDL generation transistors at each end of the NAND string. Based on process variances during manufacturing, it is likely that one of the two GIDL generation transistors at an end of the NAND string is best suited for GIDL.

For example, the GIDL generation transistors have an abrupt PN junction to generate the charge carriers for GIDL and, during fabrication, a phosphorous diffusion is performed at the polysilicon channel of the GIDL generation transistors. In some cases, the GIDL generation transistor with the shallowest phosphorous diffusion is the GIDL generation transistor that generates the charge carriers during erase. However, in some embodiments charge carriers can be generated by GIDL at multiple GIDL generation transistors at a particular side of the NAND string.

Memory holes/Vertical columns 428 and 430 are depicted protruding through the drain side select layers, source side select layers, dummy word line layers, GIDL generation transistor layers and word line layers. In one embodiment, each memory hole/vertical column comprises a vertical NAND string. Below the memory holes/vertical columns and the layers listed below is substrate 464, an insulating film 466 on the substrate, and source line SL. The NAND string of memory hole/vertical column 428 has a source end at a bottom of the stack and a drain end at a top of the stack. As in agreement with FIG. 4C, FIG. 4D show vertical memory hole/column 428 connected to bit line 442 via connector 468.

For ease of reference, drain side select layers, source side select layers, dummy word line layers, GIDL generation transistor layers and data word line layers collectively are referred to as conductive layers.

In one embodiment, the conductive layers are made from a combination of TiN and Tungsten. In other embodiments, other materials can be used to form the conductive layers, such as doped polysilicon, metal such as Tungsten, metal silicide, such as nickel silicide, tungsten silicide, aluminum silicide or the combination thereof.

In some embodiments, different conductive layers can be formed from different materials. Between conductive layers are dielectric layers DL. In one embodiment, the dielectric layers are made from SiO₂. In other embodiments, other dielectric materials can be used to form the dielectric layers.

The non-volatile memory cells are formed along memory holes/vertical columns which extend through alternating conductive and dielectric layers in the stack. In one embodiment, the memory cells are arranged in NAND strings. The word line layers WL0-W161 connect to memory cells (also called data memory cells). Dummy word line layers connect to dummy memory cells.

A dummy memory cell does not store and is not eligible to store host data (data provided from the host, such as data from a user of the host), while a data memory cell is eligible to store host data. In some embodiments, data memory cells and dummy memory cells may have a same structure. Drain side select layers SGD0 and SGD1 are used to electrically connect and disconnect NAND strings from bit lines. Source side select layers SGS0 and SGS1 are used to electrically connect and disconnect NAND strings from the source line SL.

FIG. 4D shows that the memory array is implemented as a two tier architecture, with the tiers separated by a Joint area. In one embodiment it is expensive and/or challenging to etch so many word line layers intermixed with dielectric layers. To ease this burden, one embodiment includes laying down a first stack of word line layers (e.g., WL0-WL80) alternating with dielectric layers, laying down the Joint area, and laying down a second stack of word line layers (e.g., WL81-WL161) alternating with dielectric layers. The Joint area are positioned between the first stack and the second stack. In one embodiment, the Joint areas are made from the same materials as the word line layers. In other embodiments, there can no Joint area or there can be multiple Joint areas.

FIG. 4E depicts a portion of one embodiment of a three dimensional memory structure 202 showing a cross-sectional view along line BB of FIG. 4C. This cross sectional view cuts through memory holes/vertical columns (NAND strings) 416 and 470 of region 454 (see FIG. 4C). FIG. 4E shows the same alternating conductive and dielectric layers as FIG. 4D.

FIG. 4E also shows isolation region 446. Isolation regions 446, 448, 450 and 452) occupy space that would have been used for a portion of the memory holes/vertical columns/NAND stings. For example, isolation region 446 occupies space that would have been used for a portion of memory hole/vertical column 470. More specifically, a portion (e.g., half the diameter) of vertical column 470 has been removed in layers SGDT0, SGDT1, SGD0, and SGD1 to accommodate isolation region 446.

Thus, while most of the vertical column 470 is cylindrical (with a circular cross section), the portion of vertical column 470 in layers SGDT0, SGDT1, SGD0, and SGD1 has a semi-circular cross section. In one embodiment, after the stack of alternating conductive and dielectric layers is formed, the stack is etched to create space for the isolation region and that space is then filled in with SiO₂. This structure allows for separate control of SGDT0, SGDT1, SGD0, and SGD1 for regions 454, 456, 458, 460, and 462.

FIG. 4F depicts a cross sectional view of region 472 of FIG. 4D that includes a portion of memory hole/vertical column 428. In one embodiment, the memory holes/vertical columns are round. However, in other embodiments other shapes can be used. In one embodiment, memory hole/vertical column 428 includes an inner core layer 474 that is made of a dielectric, such as SiO₂. Other materials can also be used.

Surrounding inner core 474 is polysilicon channel 476. Materials other than polysilicon can also be used. Note that it is the channel 476 that connects to the bit line and the source line. Surrounding channel 476 is a tunneling dielectric 478. In one embodiment, tunneling dielectric 478 has an ONO structure. Surrounding tunneling dielectric 478 is charge trapping layer 480, such as (for example) Silicon Nitride. Other memory materials and structures can also be used. The technology described herein is not limited to any particular material or structure.

FIG. 4F depicts dielectric layers DL as well as word line layers WL160, WL159, WL158, WL157, and WL156. Each of the word line layers includes a word line region 482 surrounded by an aluminum oxide layer 484, which is surrounded by a blocking oxide layer 486. In other embodiments, the blocking oxide layer can be a vertical layer parallel and adjacent to charge trapping layer 480. The physical interaction of the word line layers with the vertical column forms the memory cells.

Thus, in one embodiment a memory cell includes channel 476, tunneling dielectric 478, charge trapping layer 480, blocking oxide layer 486, aluminum oxide layer 484 and word line region 482. For example, word line layer WL160 and a portion of memory hole/vertical column 428 comprise a memory cell MC1. Word line layer WL159 and a portion of memory hole/vertical column 428 comprise a memory cell MC2. Word line layer WL158 and a portion of memory hole/vertical column 428 comprise a memory cell MC3. Word line layer WL157 and a portion of memory hole/vertical column 428 comprise a memory cell MC4. Word line layer WL156 and a portion of memory hole/vertical column 428 comprise a memory cell MC5. In other architectures, a memory cell may have a different structure; however, the memory cell would still be the storage unit.

When a memory cell is programmed, electrons are stored in a portion of the charge trapping layer 480 which is associated with (e.g. in) the memory cell. These electrons are drawn into the charge trapping layer 480 from the channel 476, through the tunneling dielectric 478, in response to an appropriate voltage on word line region 482. The threshold voltage (Vth) of a memory cell is increased in proportion to the amount of stored charge.

In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as GIDL.

FIG. 4G is a schematic diagram of a portion of the three dimensional memory array 202 depicted in in FIGS. 4B-4F. FIG. 4G shows physical data word lines WL0-WL161 running across the entire block. The structure of FIG. 4G corresponds to a portion 412 in Block 2 of FIG. 4B, including bit line 436. Within the block, in one embodiment, each bit line is connected to five NAND strings, one in each region of regions 454, 456, 458, 460, 462.

Thus, FIG. 4G shows bit line 436 connected to NAND string NS0 (which corresponds to memory hole/vertical column 418 of region 454), NAND string NS1 (which corresponds to memory hole/vertical column 420 of region 456), NAND string NS2 (which corresponds to vertical column 422 of region 458), NAND string NS3 (which corresponds to memory hole/vertical column 426 of region 460), and NAND string NS4 (which corresponds to memory hole/vertical column 432 of region 462).

Drain side select line/layer SGD0 is separated by isolation regions isolation regions 446, 448, 450 and 452 to form SGD0-s0, SGD0-s1, SGD0-s2, SGD0-s3 and SGD0-s4 in order to separately connect to and independently control regions 454, 456, 458, 460, 462.

Similarly, drain side select line/layer SGD1 is separated by isolation regions 446, 448, 450 and 452 to form SGD1-s0, SGD1-s1, SGD1-s2, SGD1-s3 and SGD1-s4 in order to separately connect to and independently control regions 454, 456, 458, 460, 462.

Drain side GIDL generation transistor control line/layer SGDT0 is separated by isolation regions 446, 448, 450 and 452 to form SGDT0-s0, SGDT0-s1, SGDT0-s2, SGDT0-s3 and SGDT0-s4 in order to separately connect to and independently control regions 454, 456, 458, 460, 462.

Drain side GIDL generation transistor control line/layer SGDT1 is separated by isolation regions 446, 448, 450 and 452 to form SGDT1-s0, SGDT1-s1, SGDT1-s2, SGDT1-s3 and SGDT1-s4 in order to separately connect to and independently control regions 454, 456, 458, 460, 462.

FIG. 4G only shows NAND strings connected to bit line 436. However, a full schematic of the block would show every bit line and five vertical NAND strings (that are in separate regions) connected to each bit line.

Although the example memories of FIGS. 4B-4G are three dimensional memory structures that include vertical NAND strings with charge-trapping material, other (2D and 3D) memory structures can also be used with the technology described herein.

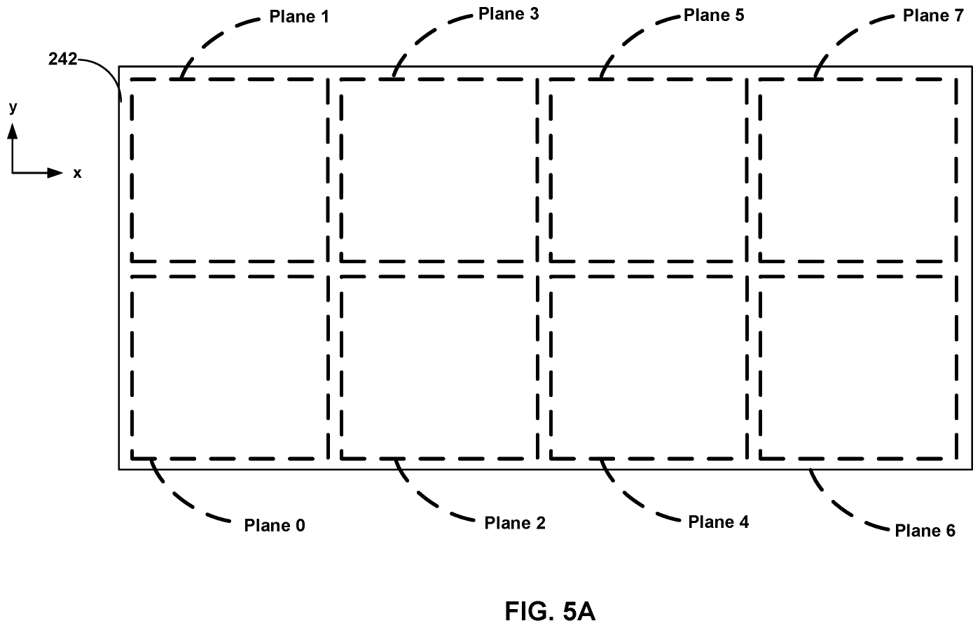

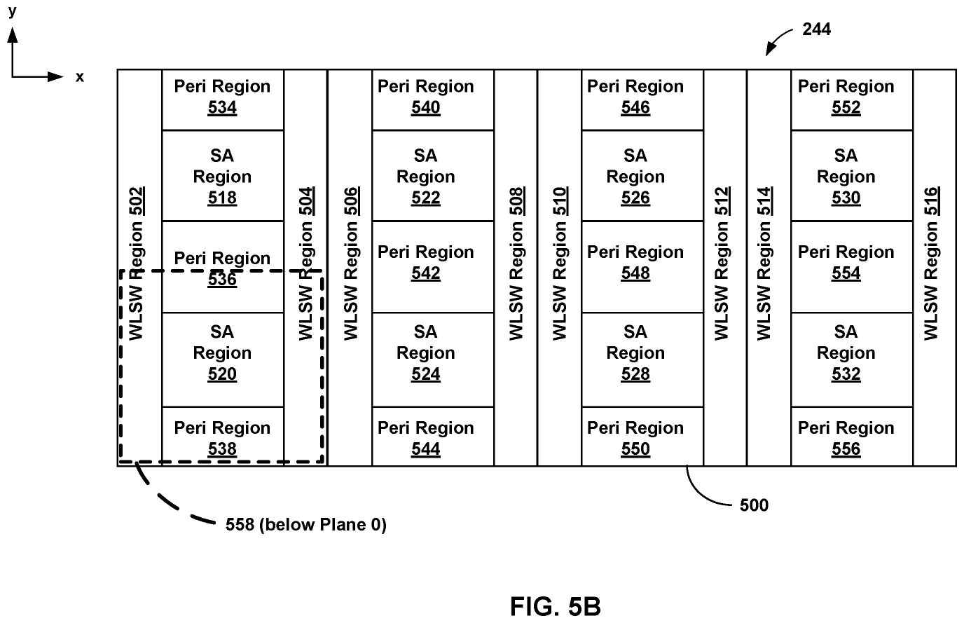

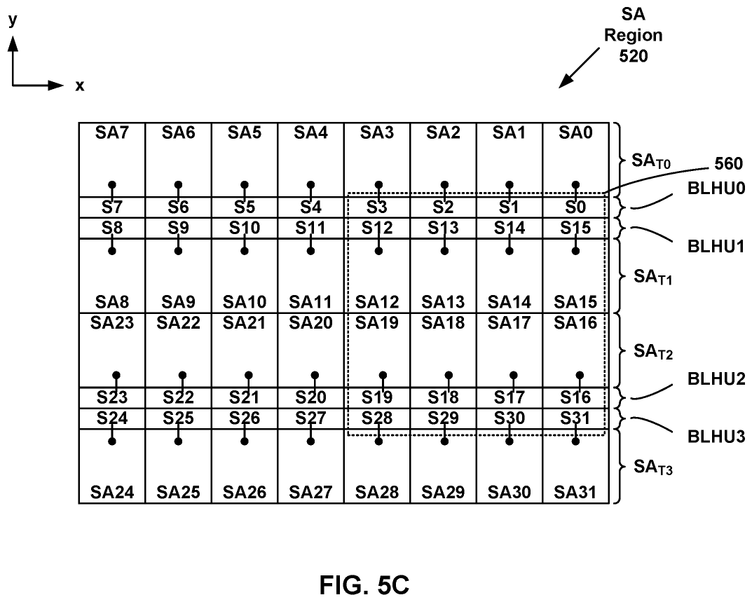

FIG. 5A depicts a top view of a memory die 242 that includes eight planes: Plane 0, Plane 1, Plane 2, Plane 3, Plane 4, Plane 5, Planer 6 and Plane 7. In other embodiments, more or less than eight planes can be implemented. In one example implementation, each plane includes a three dimensional non-volatile memory array (e.g., as described in FIGS. 4C-4G). Each of the three dimensional non-volatile memory arrays includes bit lines and word lines connected to non-volatile memory cells, as described above.

FIG. 5B depicts a top view of control die 244. Particularly, FIG. 5B is looking down on the top surface of substrate 500 of control die 244. The surface of substrate 500 is divided into various areas including a plurality of word line switch regions 502, 504, 506, 508, 510, 512, 514 and 516. Each of these word line switch regions includes a plurality of word line switches.

Control die 244 also includes a plurality of sense amplifier regions 518, 520, 522, 524, 526, 528, 530 and 532. Each of the sense amplifier regions includes sense blocks and supporting circuits.

Control die 244 further includes a plurality of peripheral circuit regions (also referred to as “Peri Regions”) 534, 536, 538, 540, 542, 544, 546, 548, 550, 552, 554 and 556. Each Peri Region includes various peripheral circuits (other than sense blocks and word line switch transistors) used to implement control die 244. For example, Peri Regions 534, 536, 538, 540, 542, 544, 546, 548, 550, 552, 554 and 556 could include the components of system control logic 208, components of row control circuitry 204, and/or the components of column control circuitry 216 (except for sense amplifiers 218) (see FIG. 2A and FIG. 2B).

In an embodiment, control die 244 of FIG. 5B is positioned below memory die 242 of FIG. 5A. That is, the eight planes depicted in FIG. 5A would be positioned above the components depicted in FIG. 5B. Note that FIG. 5B includes a dashed line surrounding section 558 of control die 244 that is positioned below plane zero (see FIG. 5A). Section 558 includes word line switch regions 502 and 504, sense amplifier region 520, Peri Region 536, and Peri Region 538.

FIG. 5C is a top view of an embodiment of sense amplifier region 520 of FIG. 5B. Sense amplifier region 520 includes multiple sense amplifier tiers SA_{T0}, SA_{T1}, SA_{T2} and SA_{T3}. Persons of ordinary skill in the art will understand that sense amplifier regions may include more or fewer than four sense amplifier tiers.

In an embodiment, each sense amplifier tier includes eight sense amplifiers. For example, sense amplifier tier SA_{T0} includes sense amplifiers SA0, SA1, SA2, . . . , SA7, sense amplifier tier SA_{T1} includes sense amplifiers SA8, SA9, SA10, . . . , SA15, and so on. Persons of ordinary skill in the art will understand that sense amplifier tiers may include more or fewer than eight sense amplifiers in each sense amplifier tier.

In an embodiment, each sense amplifier tier is coupled to one corresponding adjacent bit line hookup region. In the illustrated embodiment, sense amplifier tiers SA_{T0}, SA_{T1}, SA_{T2} and SA_{T3} are coupled to corresponding adjacent bit line hookup regions BLHU0, BLHU1, BLHU2 and BLHU3, respectively.

In an embodiment, each bit line hookup region includes multiple bit line switches, and each bit line switch is coupled to one of the sense amplifiers in the corresponding adjacent sense amplifier tiers. For example, sense amplifiers SA0, SA1, SA2, . . . , SA7 in sense amplifier tier SA_{T0} are coupled to bit line switches S0, S1, S2, . . . , S7, respectively, of corresponding adjacent bit line hookup region BLHU0. Likewise, sense amplifiers SA8, SA9, SA10, . . . , SA15 in sense amplifier tier SA_{T1} are coupled to bit line switches S8, S9, S10, . . . , S15, respectively, of corresponding adjacent bit line hookup region BLHU1, and so on.

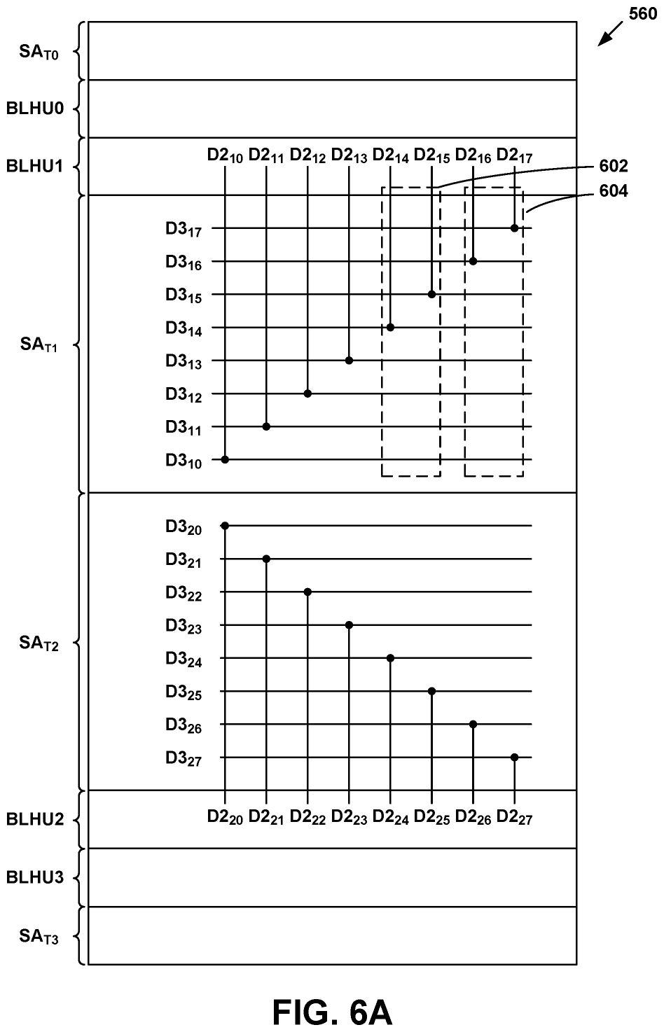

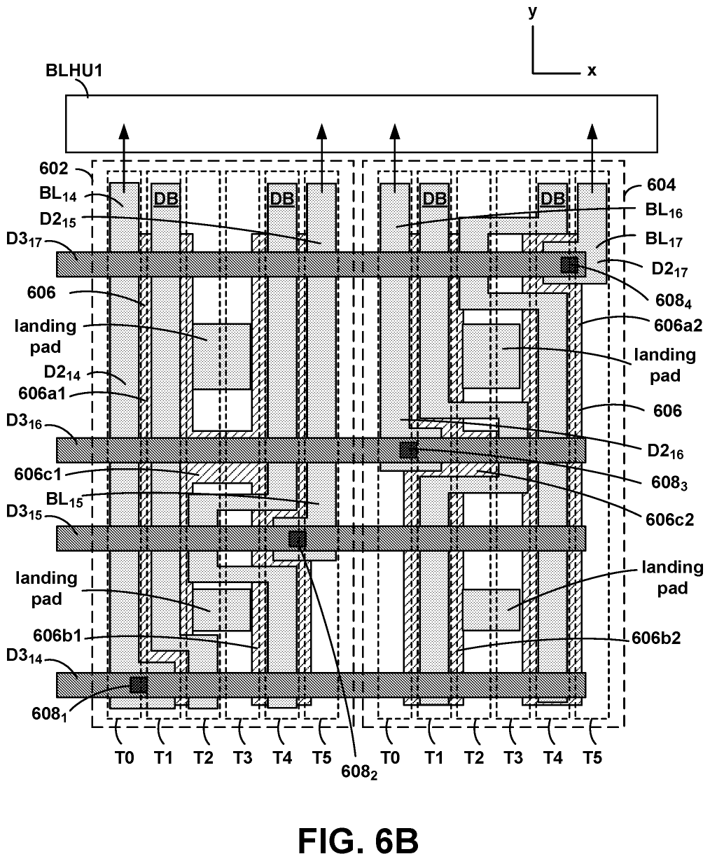

FIG. 6A depicts a simplified functional view of a portion 560 of sense amplifier region 520 of FIG. 5C. In particular, FIG. 6A depicts sense amplifier tiers SA_{T1} and SA_{T2} and corresponding bit line hookup regions BLHU1 and BLHU2, respectively, and also depicts portions of sense amplifier tiers SA_{T0} and SA_{T3} and corresponding bit line hookup regions BLHU0 and BLHU3, respectively.

In an embodiment, each sense amplifier tier includes an active area disposed on a first conductor layer (e.g., a semiconductor wafer surface), multiple conductors on a second conductor layer (D2) vertically disposed above the first conductor layer, and multiple conductors on a third conductor layer (D3) vertically disposed above the second conductor layer D2. In an embodiment, each sense amplifier tier includes a corresponding first conductor on second conductor layer D2 for each sense amp, and a corresponding third conductor on third conductor layer D3 for each sense amp.

For example, if each sense amplifier tier includes 8 sense amplifiers, each sense amplifier tier includes 8 first conductors D2₀, D2₁, D2₂, . . . , D2₇ on second conductor layer D2, and includes 8 third conductors D3₀, D3₁, D3₂, . . . , D3₇ on third conductor layer D3. For example, sense amplifier tier SA_{T1} includes first conductors D2₁₀, D2₁₁, D2₁₂, . . . , D2₁₇ and third conductors D3₁₀, D3₁₁, D3₁₂, . . . , D3₁₇. Likewise, sense amplifier tier SA_{T2} includes first conductors D2₂₀, D2₂₁, D2₂₂, . . . , D2₂₇ and third conductors D3₂₀, D3₂₁, D3₂₂, . . . , D3₂₇.

In an embodiment, each of first conductors D2₀, D2₁, D2₂, . . . , D2₇ is coupled to a corresponding one of third conductors D3₀, D3₁, D3₂, . . . , D3₇, respectively. For example, in sense amplifier tier SA_{T1} first conductors D2₁₀, D2₁₁, D2₁₂, . . . , D2₁₇ are coupled to corresponding third conductors, D3₁₀, D3₁₁, D3₁₂, . . . , D3₁₇, respectively, and in sense amplifier tier SA_{T2} first conductors D2₂₀, D2₂₁, D2₂₂, . . . , D2₂₇ are coupled to third conductors D3₂₀, D3₂₁, D3₂₂, . . . , D3₂₇, respectively.

In addition, each of first conductors D2₀, D2₁, D2₂, . . . , D2₇ is coupled to a corresponding switch (not shown) in the corresponding adjacent bit line hookup region. For example, in sense amplifier tier SA_{T1} first conductors D2₁₀, D2₁₁, D2₁₂, . . . , D2₁₇ are each coupled to a corresponding switch (not shown) in corresponding adjacent bit line hookup region BLHU1. Likewise, in sense amplifier tier SA_{T2} first conductors D2₂₀, D2₂₁, D2₂₂, . . . , D2₂₇ are each coupled to a corresponding switch (not shown) in corresponding adjacent bit line hookup region BLHU2.

In an embodiment, first conductors D2₀, D2₁, D2₂, . . . , D2₇ in a sense amplifier tier are coupled to one corresponding adjacent bit line hookup region. For example, first conductors D2₁₀, D2₁₁, D2₁₂, . . . , D2₁₇ in sense amplifier tier SA_{T1} are all coupled to one corresponding adjacent bit line hookup region BLHU1. Likewise, first conductors D2₂₀, D2₂₁, D2₂₂, . . . , D2₂₇ in sense amplifier tier SA_{T2} are all coupled to one corresponding adjacent bit line hookup region BLHU2.

In an embodiment, first conductors D2₀, D2₁, D2₂, . . . , D2₇, corresponding third conductors D3₀, D3₁, D3₂, . . . , D3₇, and the corresponding switches in the corresponding adjacent bit line hookup region form a network used to couple NAND strings of memory cells in a memory array (e.g., memory array 202 of FIGS. 2A-2B) to a corresponding sense amplifier in the sense amplifier tiers. In an embodiment, first conductors D2₀, D2₁, D2₂, . . . , D2₇ are bit lines.

For example, NAND strings NS₁₀, NS₁₁, NS₁₂, . . . , NS₁₇ (not shown) in a memory array are coupled via corresponding first conductors D2₁₀, D2₁₁, D2₁₂, . . . , D2₁₇, corresponding third conductors D3₁₀, D3₁₁, D3₁₂, . . . , D3₁₇, and corresponding switches (not shown) to corresponding sense amplifiers in sense amplifier tier SA_{T1}.

Likewise, NAND strings NS₂₀, NS₂₁, NS₂₂, . . . , NS₂₇ (not shown) in a memory array are coupled via corresponding first conductors D2₂₀, D2₂₁, D2₂₂, . . . , D2₂₇, corresponding third conductors D3₂₀, D3₂₁, D3₂₂, . . . , D3₂₇, and corresponding switches (not shown) to corresponding sense amplifiers in sense amplifier tier SA_{T2}, and so on.

In an embodiment, each sense amplifier tier includes multiple sense amplifier unit circuits that include multiple sense amplifiers. In an embodiment, each sense amplifier unit circuit includes 2 sense amplifiers, although sense amplifier unit circuits may include more or fewer than two sense amplifiers. FIG. 6A depicts sense amplifier unit circuits 602 and 604. In an embodiment, each sense amplifier tier includes four sense amplifier unit circuits. Persons of ordinary skill in the art will understand that each sense amplifier tier alternatively may include more or fewer than four sense amplifier unit circuits.

FIG. 6B depicts a plan view of an example layout of sense amplifier unit circuits 602 and 604 of FIG. 6A. In particular, sense amplifier unit circuits 602 and 604 each include portions of first conductors D2₁₄, D2₁₅, D2₁₆, and D2₁₇, second conductors DB, third conductors D3₁₄, D3₁₅, D3₁₆, and D3₁₇, landing pads, active areas 606 and contacts 608. In an embodiment, second conductors DB are used for carrying bus signals, and landing pads are used to make connections to upper metal layers (not shown). Persons of ordinary skill in the art will understand that sense amplifier unit circuits 602 and 604 may include additional or different material layers.

In an embodiment, active areas 606 are disposed on a first conductor layer (e.g., a semiconductor wafer surface), first conductors D2₁₄, D2₁₅, D2₁₆, and D2₁₇, second conductors DB and landing pads are disposed on a second conductor layer above active areas 606, and third conductors D3₁₄, D3₁₅, D3₁₆, and D3₁₇ are disposed on a third conductor layer above active areas 606. In an embodiment, the third conductor layer is disposed above the second conductor layer. Persons of ordinary skill in the art will understand that sense amplifier unit circuits 602 and 604 may include additional semiconductor layers.

In an embodiment, first conductors D2₁₄, D2₁₅, D2₁₆, and D2₁₇ are substantially parallel to second conductors DB, and first conductors D2₁₄, D2₁₅, D2₁₆, and D2₁₇ are substantially perpendicular to third conductors D3₁₄, D3₁₅, D3₁₆, and D3₁₇. In an embodiment, first conductors D2₁₄, D2₁₅, D2₁₆, and D2₁₇ and second conductors DB are substantially parallel to a first axis (e.g., a y-axis), and third conductors D3₁₄, D3₁₅, D3₁₆, and D3₁₇ are substantially parallel to a second axis (e.g., an x-axis).

In an embodiment, sense amplifier unit circuits 602 and 604 each include an active area 606 that includes transistors used to form two sense amplifiers. In an embodiment, sense amplifier unit circuit 602 includes an active area 606 that include a first active area portion 606a1, a second active area portion 606b1 and a third active area portion 606c1 that couples first active area portion 606al and second active area portion 606b1. In an embodiment, sense amplifier unit circuit 604 includes an active area 606 that includes a first active area portion 606a2, a second active area portion 606b2 and a third active area portion 606c2 that couples first active area portion 606a2 and second active area portion 606b2.

In an embodiment, first active area portion 606al and second active area portion 606b1 each include transistors that are used to form a first sense amplifier and a second sense amp, respectively, of sense amplifier unit circuit 602. In an embodiment, first active area portion 606a2 and second active area portion 606b2 each include transistors that are used to form a first sense amplifier and a second sense amp, respectively, of sense amplifier unit circuit 604.

In an embodiment, first conductors D2₁₄, D2₁₅, D2₁₆, and D2₁₇ are coupled to third conductors D3₁₄, D3₁₅, D3₁₆, and D3₁₇, respectively, via contacts 608. In an embodiment, first conductors D2₁₄, D2₁₅, D2₁₆, and D2₁₇ are coupled to bit line hookup region BLHU1.

For example, first conductor D2₁₄ (also designated as bit line BL₁₄) is coupled via contact 608₁ to third conductor D3₁₄, and also is coupled to bit line hookup region BLHU1.

Likewise, first conductor D2₁₅ (also designated as bit line BL₁₅) is coupled via contact 608₂ to third conductor D3₁₅, and also is coupled to bit line hookup region BLHU1.

Similarly, third conductor D3₁₆ first conductor D2₁₆ (also designated as bit line BL₁₆) is coupled via contact 608₃ to third conductor D3₁₆, and also is coupled to bit line hookup region BLHU1.

Further, first conductor D2₁₇ (also designated as bit line BL₁₇) is coupled via contact 608₄ to third conductor D3₁₇, and also is coupled to bit line hookup region BLHU1.

In semiconductor circuit layout design, parallel conductive traces are laid out in integrated circuit layout “tracks.” In the example layout depicted in FIG. 6B, each of sense amplifier unit circuits 602 and 604 includes 6 integrated circuit layout tracks T0, T1, T2, . . . , T5 on second conductor layer D2. In an embodiment, the 6 integrated circuit layout tracks on second conductor layer D2 are assigned a specific use. That is, the 6 integrated circuit layout tracks on second conductor layer D2 include 2 (first conductor D2ₓ) bit lines, 2 second conductors DB, and one landing pad.

In an embodiment, each (first conductor D2ₓ) bit line occupies a single integrated circuit layout track on second conductor layer D2, each second conductor DB occupies a single integrated circuit layout track on second conductor layer D2, and each landing pad occupies two integrated circuit layout tracks on second conductor layer D2. In an embodiment, because of the required current density and other characteristics, the width of the landing pads cannot be further reduced, and require two integrated circuit layout tracks on second conductor layer D2.

To increase memory array density, it would be desirable to reduce the size of the sense amplifier unit circuits. One technique to reduce the size is to reduce the width of the conductive traces, such as bit lines (first conductors D2₂₀, D2₂₁, D2₂₂, . . . , D2₂₇). However, due to photolithography limits, there is a minimum feature width that cannot be further reduced. For example, in an embodiment the minimum conductive trace width is about 45 nm.

As described above, each of sense amplifier unit circuits 602 and 604 includes active areas 606 for forming two sense amplifiers. Thus, because each of sense amplifier unit circuit 602 and 604 includes 6 integrated circuit layout tracks on second conductor layer D2, there are 3 integrated circuit layout tracks per sense amplifier.

Technology is described to shrink the size of the sense amplifier unit circuits by decreasing the number of integrated circuit layout tracks on second conductor layer D2 per sense amplifier. In particular, technology is described that reduces the number of integrated circuit layout tracks on second conductor layer D2 per sense amplifier from 3 integrated circuit layout tracks on second conductor layer D2 per sense amplifier to 2.5 integrated circuit layout tracks on second conductor layer D2 per sense amplifier.

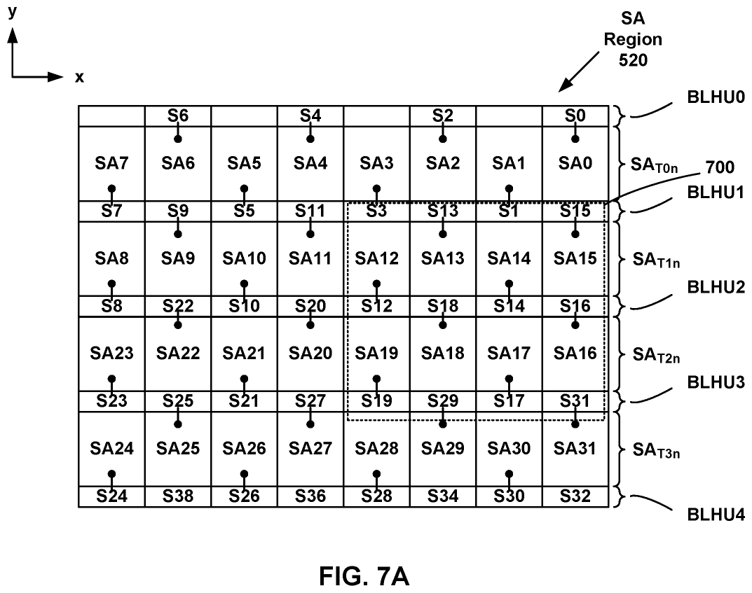

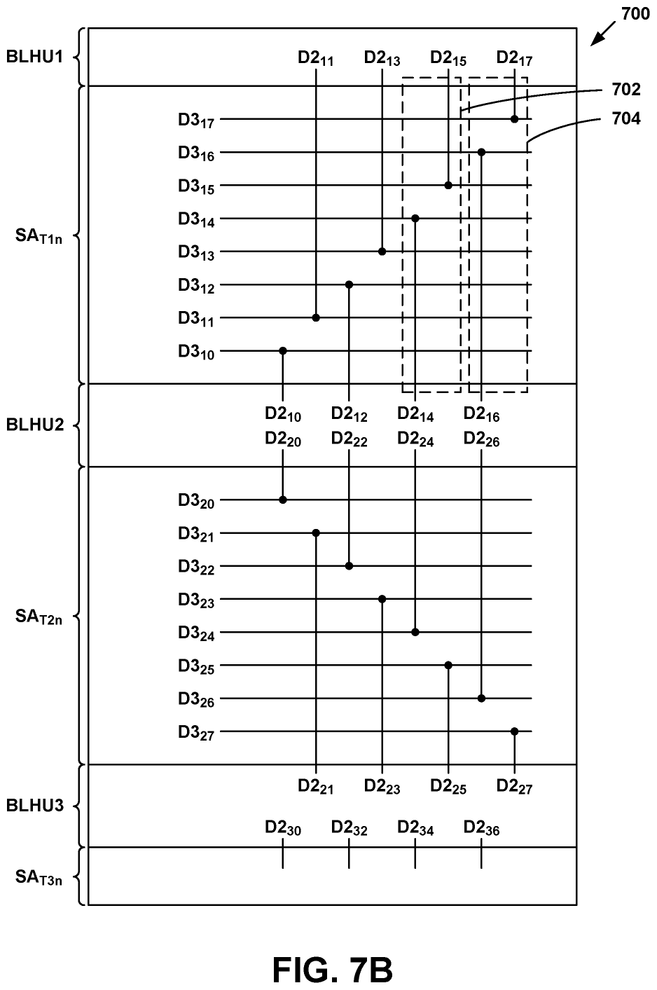

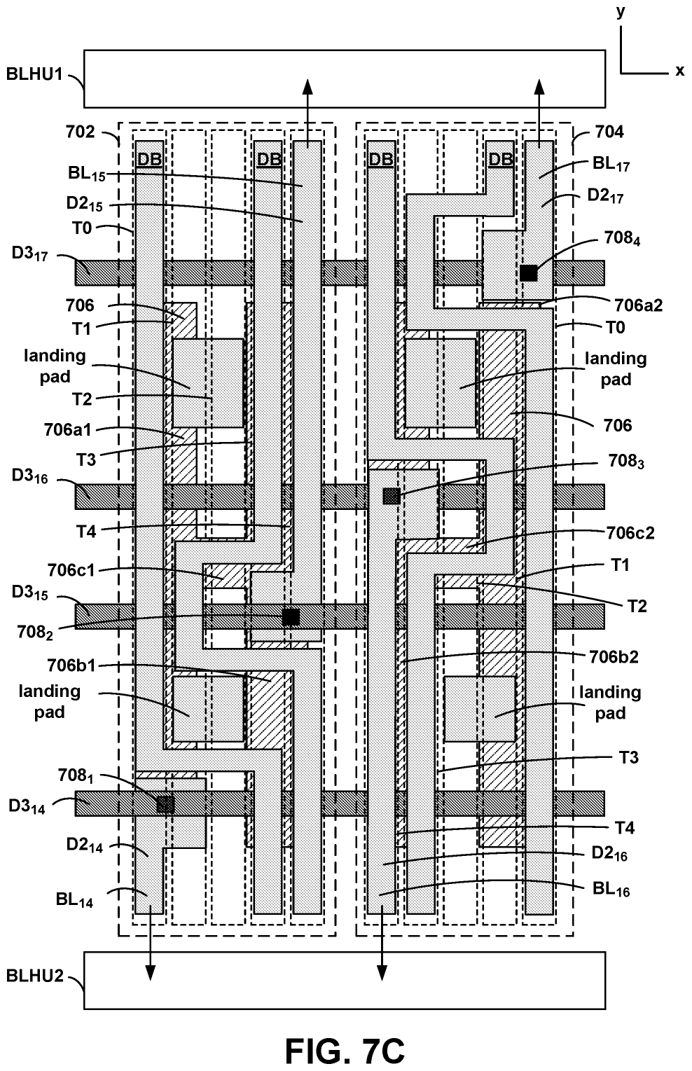

FIG. 7A is a top view of an alternative embodiment of sense amplifier region 520 of FIG. 5B. Sense amplifier region 520 includes multiple sense amplifier tiers SA_{T0n}, SA_{T1n}, SA_{T2n} and SA_{T3n}. Persons of ordinary skill in the art will understand that sense amplifier regions may include more or fewer than four sense amplifier tiers.

In an embodiment, each sense amplifier tier includes eight sense amplifiers. For example, sense amplifier tier SA_{T0n} includes sense amplifiers SA0, SA1, SA2, . . . , SA7, sense amplifier tier SA_{T1n} includes sense amplifiers SA8, SA9, SA10, . . . , SA15, and so on. Persons of ordinary skill in the art will understand that sense amplifier tiers may include more or fewer than eight sense amplifiers in each sense amplifier tier.

In an embodiment, each sense amplifier tier is coupled to two corresponding adjacent bit line hookup regions, one in a first direction (e.g., in the +y-direction) relative to the sense amplifier tier, and a second in a second direction (e.g., in the −y-direction) relative to the sense amplifier tier.

In the illustrated embodiment, sense amplifier tier SA_{T0n} is coupled to corresponding adjacent bit line hookup region BLHU0 in the +y-direction relative to sense amplifier tier SA_{T0n}, and also is coupled to corresponding adjacent bit line hookup region BLHU1 in the −y-direction relative to sense amplifier tier SA_{T0n}.

Similarly, sense amplifier tier SA_{T1n} is coupled to corresponding adjacent bit line hookup region BLHU1 in the +y-direction relative to sense amplifier tier SA_{T1n}, and also is coupled to corresponding adjacent bit line hookup region BLHU2 in the −y-direction relative to sense amplifier tier SA_{T1n}.

Likewise, sense amplifier tier SA_{T2n} is coupled to corresponding adjacent bit line hookup region BLHU2 in the +y-direction relative to sense amplifier tier SA_{T2n}, and also is coupled to corresponding adjacent bit line hookup region BLHU3 in the −y-direction relative to sense amplifier tier SA_{T2n}.

Also, sense amplifier tier SA_{T3n} is coupled to corresponding adjacent bit line hookup region BLHU3 in the +y-direction relative to sense amplifier tier SA_{T3n}, and also is coupled to corresponding adjacent bit line hookup region BLHU4 in the −y-direction relative to sense amplifier tier SA_{T3n}.

In an embodiment, each bit line hookup region includes multiple bit line switches, and each bit line switch is coupled to one of the sense amplifiers in a corresponding adjacent sense amplifier tier either in a first direction (e.g., in the +y-direction) or in a second direction (e.g., in the −y-direction) relative to the bit line switch.

For example, bit line hookup region BLHU0 includes bit line switches S0, S2, S4, and S6 which are coupled to sense amplifiers SA0, SA2, SA4, and SA6, respectively, in corresponding adjacent sense amplifier tier SA_{T0n} disposed in the −y-direction relative to bit line switches S0, S2, S4, and S6.

Likewise, bit line hookup region BLHU1 includes bit line switches S1, S3, S5, and S7 which are coupled to sense amplifiers SA1, SA3, SA5, and SA7, respectively, in corresponding adjacent sense amplifier tier SA_{T0n} disposed in the +y-direction relative to bit line switches S1, S3, S5, and S7.

Similarly, bit line hookup region BLHU1 includes bit line switches S9, S11, S13, and S15 which are coupled to sense amplifiers SA9, SA11, SA13, and SA15, respectively, in corresponding adjacent sense amplifier tier SA_{T1n} disposed in the −y-direction relative to bit line switches S9, S11, S13, and S15, and so on.

FIG. 7B depicts a simplified functional view of a portion 700 of sense amplifier region 520 of FIG. 7A. In particular, FIG. 7B depicts sense amplifier tiers SA_{T1n} and SA_{T2n} and corresponding bit line hookup regions BLHU1, BLHU2 and BLHU3, and also depicts portions of sense amplifier tier SA_{T3n}.

In an embodiment, each sense amplifier tier includes multiple conductors on second conductor layer D2 and multiple conductors on third conductor layer D3 vertically disposed above second conductor layer D2. In an embodiment, each sense amplifier tier includes a corresponding first conductor on second conductor layer D2 for each sense amp, and a corresponding third conductor on third conductor layer D3 for each sense amp.

For example, if each sense amplifier tier includes 8 sense amplifiers, each sense amplifier tier includes 8 first conductors D2₀, D2₁, D2₂, . . . , D2₇ on second conductor layer D2, and includes 8 third conductors D3₀, D3₁, D3₂, . . . , D3₇ on third conductor layer D3. For example, sense amplifier tier SA_{T1n} includes first conductors D2₁₀, D2₁₁, D2₁₂, . . . , D2₁₇ and third conductors D3₁₀, D3₁₁, D3₁₂, . . . , D3₁₇. Likewise, sense amplifier tier SA_{T2n} includes first conductors D2₂₀, D2₂₁, D2₂₂, . . . , D2₂₇ and third conductors D3₂₀, D3₂₁, D3₂₂, . . . , D3₂₇.

In an embodiment, each of first conductors D2₀, D2₁, D2₂, . . . , D2₇ is coupled to a corresponding one of third conductors D3₀, D3₁, D3₂, . . . , D3₇, respectively. For example, in sense amplifier tier SA_{T1n} first conductors D2₁₀, D2₁₁, D2₁₂, . . . , D2₁₇ are coupled to corresponding third conductors D3₁₀, D3₁₁, D3₁₂, . . . , D3₁₇, respectively, and in sense amplifier tier SA_{T2n} first conductors D2₂₀, D2₂₁, D2₂₂, . . . , D2₂₇ are coupled to third conductors D3₂₀, D3₂₁, D3₂₂, . . . , D3₂₇, respectively.

In addition, a first subset of first conductors D2₀, D2₁, D2₂, . . . , D2₇ is coupled to a corresponding switch (not shown) in a first of two corresponding adjacent bit line hookup regions, and a second subset of first conductors D2₀, D2₁, D2₂, . . . , D2₇ is coupled to a corresponding switch (not shown) in a second of two corresponding adjacent bit line hookup regions.

For example, sense amplifier tier SA_{T1n} includes a first subset of first conductors D2₁₁, D2₁₃, D2₁₅, and D2₁₇ that are each coupled to a corresponding switch (not shown) in a first corresponding adjacent bit line hookup region BLHU1, and includes a second subset of first conductors D2₁₀, D2₁₂, D2₁₄, and D2₁₆ that are each coupled to a corresponding switch (not shown) in a second corresponding adjacent bit line hookup region BLHU2.

Likewise, in sense amplifier tier SA_{T2n} includes a first subset of first conductors D2₂₀, D2₂₂, D2₂₄, and D2₂₆ that are each coupled to a corresponding switch (not shown) in a first corresponding adjacent bit line hookup region BLHU2, and a second subset of first conductors D2₂₁, D2₂₃, D2₂₅, and D2₂₇ that are each coupled to a corresponding switch (not shown) in a second corresponding adjacent bit line hookup region BLHU3.

Thus, in contrast to sense amplifier tiers SA_{T1} and SA_{T2} of FIG. 6A, in which first conductors D2₀, D2₁, D2₂, . . . , D2₇ in a sense amplifier tier are coupled to one corresponding bit line hookup region, in sense amplifier tiers SA_{T1n} and SA_{T2n} of FIG. 7B a first subset of first conductors D2₀, D2₁, D2₂, . . . , D2₇ in a sense amplifier tier are coupled to a first of two corresponding adjacent bit line hookup regions, and a second subset of first conductors D2₀, D2₁, D2₂, . . . , D2₇ in a sense amplifier tier are coupled to a second of two corresponding adjacent bit line hookup regions.

For example, a first subset of first conductors D2₁₁, D2₁₃, D2₁₅, and D2₁₇ in sense amplifier tier SA_{T1n} are coupled to a first corresponding adjacent bit line hookup region BLHU1, and a second subset of first conductors D2₁₀, D2₁₂, D2₁₅, and D2₁₆ in sense amplifier tier SA_{T1n} are coupled to a second corresponding adjacent bit line hookup region BLHU2.

Likewise, a first subset of first conductors D2₂₀, D2₂₂, D2₂₄, and D2₂₆ in sense amplifier tier SA_{T2n} are coupled to a first corresponding adjacent bit line hookup region BLHU2, and a second subset of first conductors D2₂₁, D2₂₃, D2₂₅, and D2₂₇ in sense amplifier tier SA_{T2n} are coupled to a second corresponding adjacent bit line hookup region BLHU3.

In an embodiment, first conductors D2₀, D2₁, D2₂, . . . , D2₇, corresponding third conductors D3₀, D3₁, D3₂, . . . , D3₇, and the corresponding switches in the two corresponding adjacent bit line hookup regions form a network used to couple NAND strings of memory cells in a memory array (e.g., memory array 202 of FIGS. 2A-2B) to a corresponding sense amplifier in the sense amplifier tiers. In an embodiment, first conductors D2₀, D2₁, D2₂, . . . , D2₇ are bit lines.

For example, NAND strings NS₁₀, NS₁₁, NS₁₂, . . . , NS₁₇ (not shown) in a memory array are coupled via first conductors D2₁₀, D2₁₁, D2₁₂, . . . , D2₁₇, corresponding third conductors D3₁₀, D3₁₁, D3₁₂, . . . , D3₁₇, and corresponding switches (not shown) to corresponding sense amplifiers in sense amplifier tier SA_{T1n}.

Likewise, NAND strings NS₂₀, NS₂₁, NS₂₂, . . . , NS₂₇ (not shown) in a memory array are coupled via first conductors D2₂₀, D2₂₁, D2₂₂, . . . , D2₂₇, corresponding third conductors D3₂₀, D3₂₁, D3₂₂, . . . , D3₂₇, and corresponding switches (not shown) to corresponding sense amplifiers in sense amplifier tier SA_{T2n}, and so on.

In an embodiment, each sense amplifier tier includes multiple sense amplifier unit circuits that include multiple sense amplifiers. In an embodiment, each sense amplifier unit circuit includes 2 sense amplifiers, although sense amplifier unit circuits may include more or fewer than two sense amplifiers. In an embodiment, each sense amplifier tier includes four sense amplifier unit circuits. Persons of ordinary skill in the art will understand that each sense amplifier tier alternatively may include more or fewer than four sense amplifier unit circuits. FIG. 7B depicts sense amplifier unit circuits 702 and 704.

FIG. 7C depicts a plan view of an example layout of sense amplifier unit circuits 702 and 704 of FIG. 7B. In particular, sense amplifier unit circuits 702 and 704 each include portions of first conductors D2₁₄, D2₁₅, D2₁₆, and D2₁₇, second conductors DB, third conductors D3₁₄, D3₁₅, D3₁₆, and D3₁₇, landing pads, active areas 706 and contacts 708. In an embodiment, second conductors DB are used for carrying bus signals, and landing pads are used to make connections to upper metal layers (not shown). Persons of ordinary skill in the art will understand that sense amplifier unit circuits 702 and 704 may include additional or different material layers.

In an embodiment, active areas 706 are disposed on a first conductor layer (e.g., a semiconductor wafer surface), first conductors D2₁₄, D2₁₅, D2₁₆, and D2₁₇, third conductors DB and landing pads are disposed on a second conductor layer D2 above active areas 706, and third conductors D3₁₄, D3₁₅, D3₁₆, and D3₁₇ are disposed on a third conductor layer D3 above active areas 706. In an embodiment, the third conductor layer D3 is disposed above the second conductor layer D2. Persons of ordinary skill in the art will understand that sense amplifier unit circuits 702 and 704 may include additional conductor layers.

In an embodiment, first conductors D2₁₄, D2₁₅, D2₁₆, and D2₁₇ are substantially parallel to second conductors DB, and first conductors D2₁₄, D2₁₅, D2₁₆, and D2₁₇ are substantially perpendicular to third conductors D3₁₄, D3₁₅, D3₁₆, and D3₁₇. In an embodiment, first conductors D2₁₄, D2₁₅, D2₁₆, and D2₁₇ and second conductors DB are substantially parallel to a first axis (e.g., a y-axis), and third conductors D3₁₄, D3₁₅, D3₁₆, and D3₁₇ are substantially parallel to a second axis (e.g., an x-axis).

In an embodiment, sense amplifier unit circuits 702 and 704 each include an active area 706 that includes transistors used to form two sense amplifiers. In an embodiment, sense amplifier unit circuit 702 includes an active area 706 that include a first active area portion 706a1, a second active area portion 706b1 and a third active area portion 706cl that couples first active area portion 706al and second active area portion 706b1. In an embodiment, sense amplifier unit circuit 704 includes an active area 706 that includes a first active area portion 706a2, a second active area portion 706b2 and a third active area portion 706c2 that couples first active area portion 706a2 and second active area portion 706b2.

In an embodiment, first active area portion 706al and second active area portion 706b1 each include transistors that are used to form a first sense amplifier and a second sense amp, respectively, of sense amplifier unit circuit 702. In an embodiment, first active area portion 706a2 and second active area portion 706b2 each include transistors that are used to form a first sense amplifier and a second sense amp, respectively, of sense amplifier unit circuit 704.

In an embodiment, first conductors D2₁₄, D2₁₅, D2₁₆, and D2₁₇ are coupled to third conductors D3₁₄, D3₁₅, D3₁₆, and D3₁₇, respectively, via contacts 708. In an embodiment, first conductors D2₁₄, D2₁₅, D2₁₆, and D2₁₇ are coupled to one of two corresponding adjacent bit line hookup regions.

For example, first conductor D2₁₄ (also designated as bit line BL₁₄) is coupled via contact 7081 to third conductor D3₁₄, and also is coupled to a first corresponding adjacent bit line hookup region BLHU2.

Similarly, first conductor D2₁₅ (also designated as bit line BL₁₅) is coupled via contact 7082 to third conductor D3₁₅, and also is coupled to a second corresponding bit line hookup region BLHU1.

Likewise, first conductor D2₁₆ (also designated as bit line BL₁₆) is coupled via contact 7083 to third conductor D3₁₆, and also is coupled to first corresponding adjacent bit line hookup region BLHU2.

Also, first conductor D2₁₇ (also designated as bit line BL₁₇) is coupled via contact 7084 to third conductor D3₁₇, and also is coupled to second corresponding adjacent bit line hookup region BLHU1.

As described above, in semiconductor circuit design, parallel conductive traces are laid out in integrated circuit layout tracks. In the example layout depicted in FIG. 7C, each of sense amplifier unit circuits 702 and 704 includes 5 integrated circuit layout tracks TO, T1, T2, . . . , T4 on second conductor layer D2. In an embodiment, the 5 integrated circuit layout tracks on second conductor layer D2 are assigned a specific use. That is, the 5 integrated circuit layout tracks on second conductor layer D2 include 2 (first conductor D2ₓ) bit lines, 2 second conductors DB, and one landing pad.

In an embodiment, each (first conductor D2ₓ) bit line occupies a single integrated circuit layout track on second conductor layer D2, each second conductor DB occupies a single integrated circuit layout track on second conductor layer D2, and each landing pad occupies two integrated circuit layout tracks on second conductor layer D2, just like the example layout of FIG. 6B.

But in contrast to the example layout of FIG. 6B, because first conductors D2₁₄, D2₁₅, D2₁₆, and D2₁₇ are coupled to adjacent bit line hookup regions in a first direction (e.g., in the +y-direction) and a second direction (e.g., in the −y-direction) relative to the sense amplifier tier, within each of sense amplifier unit circuits 702 and 704 two first conductors D2ₓ can “share” an integrated circuit layout track on second conductor layer D2 along the first direction with one of the second conductors DB.

For example, in FIG. 7C first conductor D2₁₄ shares integrated circuit layout track TO of sense amplifier unit circuit 702 along part of the first direction (y-direction) with a first second conductor DB, and first conductor D2₁₄ shares integrated circuit layout track T4 of sense amplifier unit circuit 702 along part of the first direction (y-direction) with a second second conductor DB.

Likewise, first conductor D2₁₆ shares integrated circuit layout track T4 of sense amplifier unit circuit 704 along part of the first direction (y-direction) with a first second conductor DB, and first conductor D2₁₇ shares integrated circuit layout track TO of sense amplifier unit circuit 704 along part of the first direction (y-direction) with a second second conductor DB.

As described above, each of sense amplifier unit circuits 702 and 704 includes active areas 706 for forming two sense amplifiers. Thus, because each of sense amplifier unit circuit 702 and 704 includes a total of 5 integrated circuit layout tracks on second conductor layer D2, there are 2.5 integrated circuit layout tracks on second conductor layer D2 per sense amplifier. Without wanting to be bound by any particular theory, it is believe that by using 2.5 integrated circuit layout tracks on second conductor layer D2 per sense amplifier the size of the sense amplifier unit circuits can be reduced.

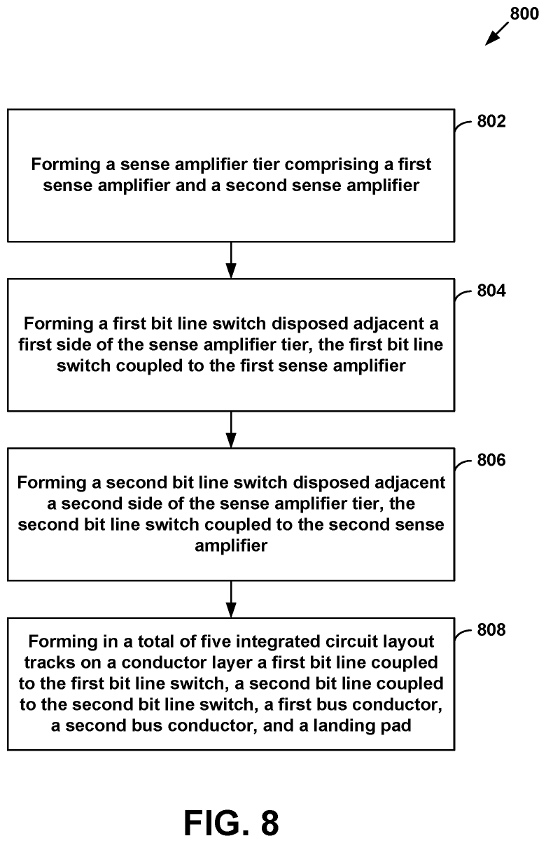

FIG. 8 is a flow diagram of an embodiment of a method 800 of fabricating a control die that includes circuits for controlling a memory die that includes a three dimensional non-volatile memory.

At step 802, forming a sense amplifier tier that includes a first sense amplifier and a second sense amplifier.

At step 804, forming a first bit line switch disposed adjacent a first side of the sense amplifier tier, the first bit line switch coupled to the first sense amplifier.

At step 806, forming a second bit line switch disposed adjacent a second side of the sense amplifier tier, the second bit line switch coupled to the second sense amplifier.

At step 808, forming in a total of five integrated circuit layout tracks on a conductor layer a first bit line coupled to the first bit line switch, a second bit line coupled to the second bit line switch, a first bus conductor, a second bus conductor, and a landing pad.

In an embodiment, an apparatus is provided that includes a first sense amplifier and a second sense amplifier, and a second conductor layer that includes two first conductors, two second conductors substantially parallel to the two first conductors, and a landing pad. The first conductors each include one integrated circuit layout track on the second conductor layer. The second conductors each include one integrated circuit layout track on the second conductor layer. The landing pad includes two integrated circuit layout tracks on the second conductor layer. The apparatus includes a total of five integrated circuit layout tracks on the second conductor layer.

In an embodiment, an apparatus is provided that includes a three dimensional non-volatile memory array that includes non-volatile memory cells, and a control circuit below the three dimensional non-volatile memory array and configured to control the three dimensional non-volatile memory array. The control circuit includes a sense amplifier tier including a plurality of sense amplifiers, a first plurality of bit lines and a second plurality of bit lines, each bit line coupled to a corresponding sense amplifier, a first bit line hookup region disposed adjacent the sense amplifier tier and coupled to the first plurality of bit lines, and a second bit line hookup region disposed adjacent the sense amplifier tier and coupled to the second plurality of bit lines. The plurality of bit lines are disposed on a second conductor layer, and the sense amplifier tier includes an integrated circuit layout including 2.5 integrated circuit layout tracks on the second conductor layer per sense amplifier.

In an embodiment, a method is provided that includes fabricating a control die that includes circuits for controlling a memory die that includes a three dimensional non-volatile memory, forming a sense amplifier tier that includes a first sense amplifier and a second sense amplifier, forming a first bit line switch disposed adjacent a first side of the sense amplifier tier, the first bit line switch coupled to the first sense amplifier, forming a second bit line switch disposed adjacent a second side of the sense amplifier tier, the second bit line switch coupled to the second sense amplifier, and forming in a total of five integrated circuit layout tracks on a conductor layer a first bit line coupled to the first bit line switch, a second bit line coupled to the second bit line switch, a first bus conductor, a second bus conductor, and a landing pad.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. An apparatus comprising:
a first sense amplifier and a second sense amplifier; and
a second conductor layer comprising two first conductors, two second conductors substantially parallel to the two first conductors, and a landing pad,
wherein:
the first conductors each comprise one integrated circuit layout track on the second conductor layer;
the second conductors each comprise one integrated circuit layout track on the second conductor layer;
the landing pad comprises two integrated circuit layout tracks on the second conductor layer; and
the apparatus comprises a total of five integrated circuit layout tracks on the second conductor layer.

2. The apparatus of claim 1, further comprising an active area disposed in a substrate, the second conductor layer disposed above the active area.

3. The apparatus of claim 1, further comprising a first conductor layer comprising an active area comprising the first sense amplifier and the second sense amplifier.

4. The apparatus of claim 1, further comprising a first conductor layer comprising a first active area portion comprising the first sense amplifier and a second active area portion comprising the second sense amplifier.

5. The apparatus of claim 1, further comprising a first conductor layer comprising a first active area portion, a second active area portion and a third active area portion that couples the first active area portion and the second active area portion.

6. The apparatus of claim 1, further comprising a third conductor layer comprising two third conductors substantially perpendicular to the two first conductors.

7. The apparatus of claim 1, further comprising a third conductor layer comprising two third conductors each coupled to a corresponding one of the first conductors.

8. The apparatus of claim 1, wherein the first conductors comprise bit lines of a three dimensional non-volatile memory array.

9. The apparatus of claim 1, wherein the two first conductors comprise:
a first first conductor coupled to a first bit line switch disposed in a first bit line hookup region; and
and a second first conductor coupled to a second bit line switch disposed in a second bit line hookup region different from the first bit line hookup region.

10. The apparatus of claim 1, wherein the two first conductors are disposed parallel to a first axis, and comprise:
a first first conductor coupled to a first bit line hookup region disposed in a first direction along the first axis; and
and a second first conductor coupled to a second bit line hookup region disposed in a second direction along the first axis,
wherein the first direction is opposite the second direction.

11. An apparatus comprising:
a three dimensional non-volatile memory array that includes non-volatile memory cells; and
a control circuit below the three dimensional non-volatile memory array and configured to control the three dimensional non-volatile memory array, the control circuit comprising:
a sense amplifier tier comprising a plurality of sense amplifiers, a first plurality of bit lines and a second plurality of bit lines, each bit line coupled to a corresponding sense amplifier;
a first bit line hookup region disposed adjacent the sense amplifier tier and coupled to the first plurality of bit lines; and
a second bit line hookup region disposed adjacent the sense amplifier tier and coupled to the second plurality of bit lines;
wherein:
the plurality of bit lines are disposed on a second conductor layer; and
the sense amplifier tier comprises an integrated circuit layout comprising 2.5 integrated circuit layout tracks on the second conductor layer per sense amplifier.

12. The apparatus of claim 11, wherein:
the first bit line hookup region comprises a first plurality of switches each coupled to a corresponding one of the sense amplifiers; and
the second bit line hookup region comprises a second plurality of switches each coupled to a corresponding one of the sense amplifiers.

13. The apparatus of claim 11, wherein:
the first bit line hookup region comprises a first plurality of switches each coupled to a corresponding one of the first plurality of bit lines; and
the second bit line hookup region comprises a second plurality of switches each coupled to a corresponding one of the second plurality of bit lines.

14. The apparatus of claim 11, wherein the sense amplifier tier comprises a plurality of sense amplifier unit circuits, each comprising two sense amplifiers and an integrated circuit layout comprising a total of 5 integrated circuit layout tracks on the second conductor layer.

15. The apparatus of claim 11, wherein the sense amplifier tier comprises a plurality of sense amplifier unit circuits, each comprising two first conductors, two second conductors substantially parallel to the two first conductors, and a landing pad all disposed on the second conductor layer.

16. The apparatus of claim 15, wherein:
the first conductors each comprise one integrated circuit layout track on the second conductor layer;
the second conductors each comprise one integrated circuit layout track on the second conductor layer;
the landing pad comprises two integrated circuit layout tracks on the second conductor layer.

17. The apparatus of claim 11, wherein the sense amplifier tier comprises a plurality of sense amplifier unit circuits, each comprising an active area disposed in a substrate, the second conductor layer disposed above the active area.

18. The apparatus of claim 11, wherein the sense amplifier tier comprises a plurality of sense amplifier unit circuits, each comprising a first conductor layer comprising an active area comprising a first sense amplifier and a second sense amplifier.

19. A method comprising:
fabricating a control die comprising circuits for controlling a memory die comprising a three dimensional non-volatile memory array by:
forming a sense amplifier tier comprising a first sense amplifier and a second sense amplifier;
forming a first bit line switch disposed adjacent a first side of the sense amplifier tier, the first bit line switch coupled to the first sense amplifier;
forming a second bit line switch disposed adjacent a second side of the sense amplifier tier, the second bit line switch coupled to the second sense amplifier; and
forming in a total of five integrated circuit layout tracks on a conductor layer a first bit line coupled to the first bit line switch, a second bit line coupled to the second bit line switch, a first bus conductor, a second bus conductor, and a landing pad.

20. The method of claim 19, further comprising forming an active area in a substrate below the conductor layer.
